(19) United States
(12) Patent Application Publication
(10) Pub. No.: US 2025/0374698 A1
(43) Pub. Date: Dec. 4, 2025

(54) IMAGE SENSOR AND METHOD OF FABRICATING THE SAME

(71) Applicant: SAMSUNG ELECTRONICS CO., LTD., Suwon-si (KR)

(72) Inventors: Hong Hyun JEON, Suwon-si (KR); Yoo Kwang KIM, Suwon-si (KR); Jong Han NAM, Suwon-si (KR); Hyeon Seop YOO, Suwon-si (KR); Won Chul CHOI, Suwon-si (KR); Jin Hwa HAN, Suwon-si (KR)

(73) Assignee: SAMSUNG ELECTRONICS CO., LTD., Suwon-si (KR)

(21) Appl. No.: 19/171,935

(22) Filed: Apr. 7, 2025

(30) Foreign Application Priority Data
Jun. 3, 2024 (KR) 10-2024-0072423

(51) Int. Cl. H10F 39/00; H10F 39/18

(52) U.S. Cl. CPC H10F 39/807; H10F 39/014; H10F 39/182

(57) ABSTRACT

An image sensor includes a substrate having a first surface and a second surface that are opposite to each other, a pixel isolation pattern in the substrate, photoelectric conversion regions, first to fourth impurity regions, and a first pad. The pixel isolation pattern defines first to fourth unit pixels in a grid arrangement with respect to a first direction and a second direction that intersects the first direction. The photoelectric conversion regions are within the first to fourth unit pixels, respectively. The first to fourth impurity regions are within the first to fourth unit pixels, respectively, and adjacent to the first surface. The first pad structure is on the first surface and contacts the first to fourth impurity regions. The first pad structure includes a first hole exposing the pixel isolation pattern between the first unit pixel and the fourth unit pixel.

### CROSS-REFERENCE TO RELATED APPLICATION

This application claims priority from Korean Patent Application No. 10-2024-0072423 filed on Jun. 3, 2024 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to an image sensor and a method of fabricating the same, and more particularly, to a Complementary Metal-Oxide Semiconductor (CMOS) image sensor and a method of fabricating the same.

### 2. Description of the Related Art

An image sensor is a type of semiconductor device that converts optical information into electrical signals. Examples of image sensors include a charge-coupled device (CCD) image sensor and a complementary metal-oxide semiconductor (CMOS) image sensor.

The image sensor can be configured in the form of a package, and the package can be configured to protect the image sensor while allowing light to be incident on the photo-receiving surface or sensing area of the image sensor.

### SUMMARY

Aspects of the present disclosure provide an image sensor with enhanced performance.

Aspects of the present disclosure also provide a method of fabricating an image sensor with enhanced performance.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided an image sensor comprising a substrate having a first surface and a second surface opposite the first surface, a pixel isolation pattern in the substrate, photo electric conversion regions, first to fourth impurity regions, and a first pad. The pixel isolation pattern defines a first unit pixel, a second unit pixel adjacent to the first unit pixel in a first direction, a third unit pixel adjacent to the first unit pixel in a second direction that intersects the first direction, and a fourth unit pixel adjacent to the second unit pixel in the second direction and adjacent to the third unit pixel in the first direction. The photoelectric conversion regions are within the first to fourth unit pixels, respectively. The first to fourth impurity regions are within the first to fourth unit pixels, respectively, and adjacent to the first surface. The first pad structure is on the first surface The first pad structure contacts the first to fourth impurity regions. The first pad structure comprises a first hole exposing the pixel isolation pattern disposed between the first unit pixel and the fourth unit pixel.

According to the aforementioned and other embodiments of the present disclosure, there is provided an image sensor comprising a substrate having a first surface and a second surface opposite the first surface, a pixel isolation pattern in the substrate, photoelectric conversion regions, element isolation patterns, and a pad structure. The pixel isolation pattern defines a plurality of unit pixels arranged two-dimensionally along a first direction and a second direction that intersects the first direction. The photoelectric conversion regions are within the respective unit pixels. The element isolation patterns define active regions within the respective unit pixels adjacent to the first surface The pad structure is on the first surface. The pixel isolation pattern comprises a first isolation portion extending in the second direction, a second isolation portion extending in the first direction, and a crossing portion where the first isolation portion and the second isolation portion intersect. The unit pixels comprise a first unit pixel, a second unit pixel separated from the first unit pixel by the first isolation portion, a third unit pixel separated from the first unit pixel by the second isolation portion, and a fourth unit pixel separated from the first unit pixel by the crossing portion. The pad structure connects the active regions of the first to fourth unit pixels and does not overlap with the crossing portion.

According to the aforementioned and other embodiments of the present disclosure, there is provided image sensor comprising a substrate having a first surface and a second surface opposite the first surface, a pixel isolation pattern in the substrate, photoelectric conversion regions, element isolation patterns, first to fourth transfer gate structures, first to fourth floating diffusion regions, and a first pad. The pixel isolation pattern defines a first unit pixel, a second unit pixel adjacent to the first unit pixel in a first direction, a third unit pixel adjacent to the first unit pixel in a second direction intersecting the first direction, and a fourth unit pixel adjacent to the second unit pixel in the second direction and adjacent to the third unit pixel in the first direction. The photoelectric conversion regions are within the first to fourth unit pixels, respectively. The element isolation patterns define active regions within the first to fourth unit pixels adjacent to the first surface, respectively. The first to fourth transfer gate structures are disposed on the active regions of the first to fourth unit pixels, respectively. The first to fourth floating diffusion regions are within the active regions adjacent to the first to fourth transfer gate structures, respectively. The first pad structure is on the first surface. The first pad structure is spaced apart from the first to fourth transfer gate structures and connects the first to fourth floating diffusion regions. The first pad structure comprises a first hole exposing the pixel isolation pattern disposed between the first unit pixel and the fourth unit pixel.

It is to be appreciated that the scope of the present disclosure is not limited to the summary described above, and full scope of the present disclosure will be apparent from the following description, drawings, and appended claims.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary circuit diagram of an image sensor, according to some embodiments of the present disclosure.

FIG. 2 is an exemplary plan view illustrating a pixel array of an image sensor, according to some embodiments of the present disclosure.

FIG. 3 is an exemplary cross-sectional view taken along line I-I of FIG. 2, according to some embodiments of the present disclosure.

FIGS. 4 to 9 are other exemplary cross-sectional views of an image sensor according to some embodiments of the present disclosure.

FIGS. 10 and 11 are other exemplary plan views of an image sensor, according to some embodiments of the present disclosure.

FIGS. 12 and 13 are various exemplary plan views of a pixel array of an image sensor, according to some embodiments of the present disclosure.

FIG. 14 is a schematic layout diagram of an image sensor, according to some embodiments of the present disclosure.

FIG. 15 is a schematic cross-sectional view of an image sensor of FIG. 14, according to embodiments of the present disclosure.

FIGS. 16 to 23 are cross-sectional views illustrating steps of a method of fabricating an image sensor, according to some embodiments of the present disclosure.

FIGS. 24 to 26 are cross-sectional views illustrating steps of a method of fabricating an image sensor, according to some embodiments of the present disclosure.

FIGS. 27 and 28 are cross-sectional views illustrating steps of a method of fabricating an image sensor according to some embodiments of the present disclosure.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the current disclosure. Instead, they are merely examples of apparatuses, systems, and methods consistent with aspects related to subject matter that may be recited in the appended claims.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure.

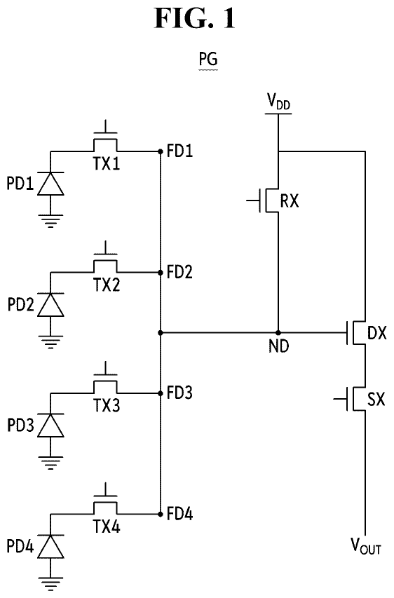

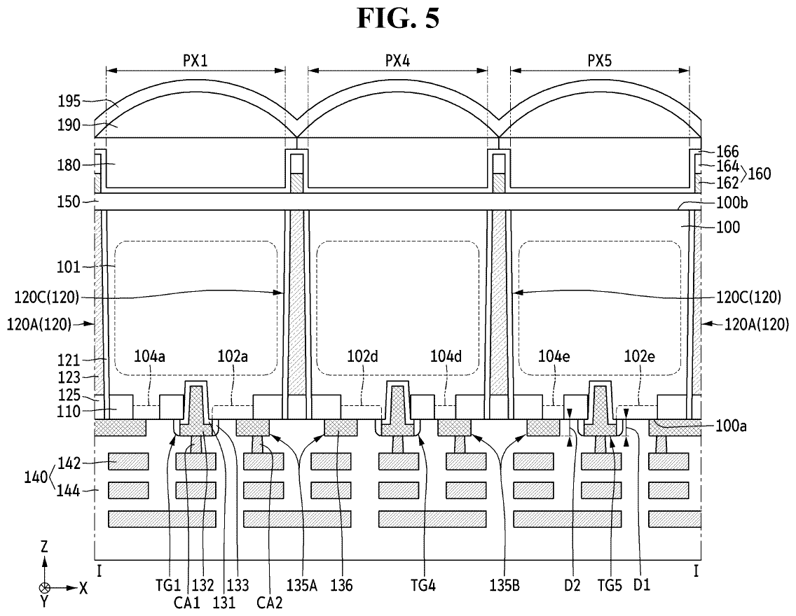

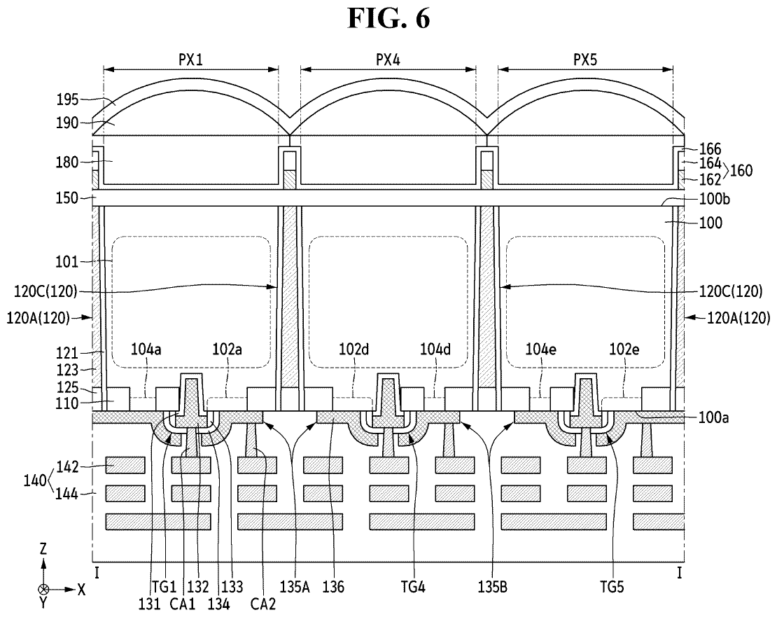

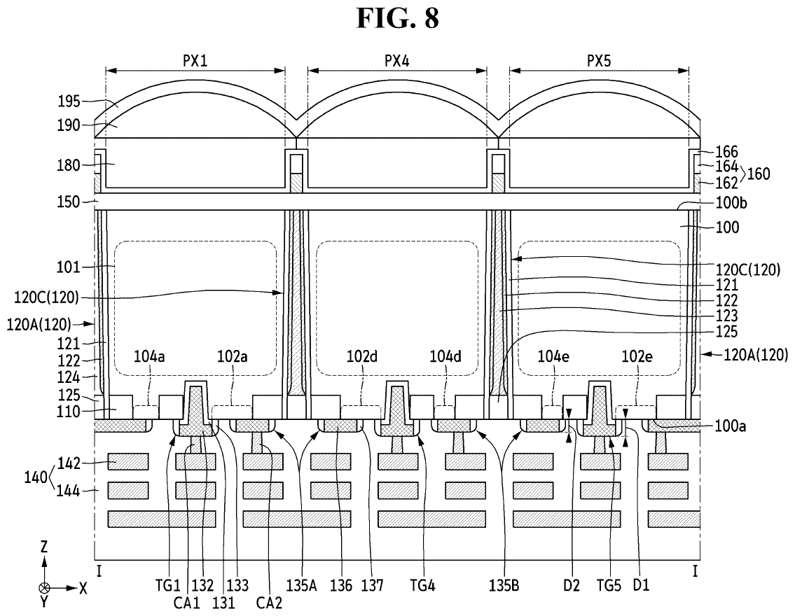

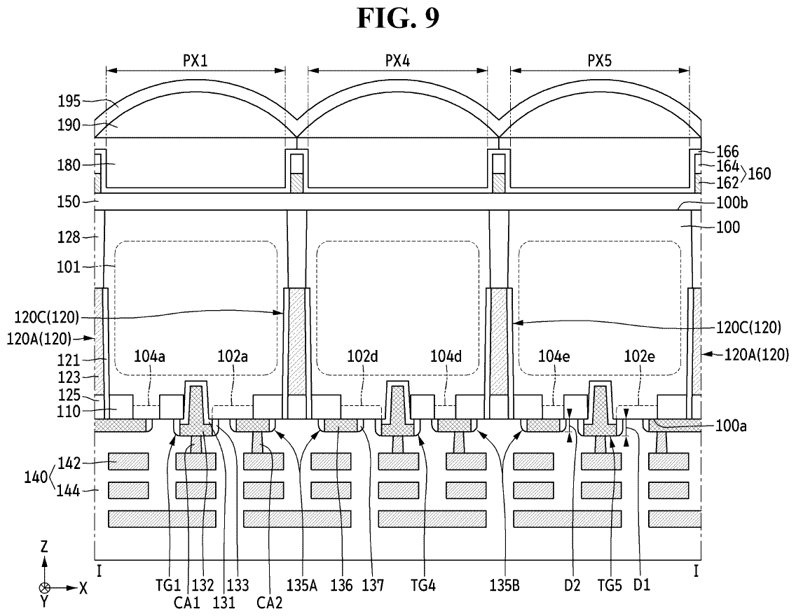

An image sensor according to exemplary embodiments of the present disclosure will hereinafter be described with reference to FIGS. 1 to 15.

FIG. 1 is an exemplary circuit diagram of an image sensor, according to some embodiments of the present disclosure.

Referring to FIG. 1, in some embodiments, the image sensor includes a unit pixel group PG. The unit pixel group PG may include first to fourth photoelectric conversion elements PD1 to PD4, first to fourth transfer transistors TX1 to TX4, first to fourth floating diffusion regions FD1 to FD4, a reset transistor RX, a drive transistor DX, and a select transistor SX.

The first to fourth photoelectric conversion elements PD1 to PD4 may each generate charges in proportion to the amount of light incident from the outside. For example, the first to fourth photoelectric conversion elements PD1 to PD4 each include one or more photodiodes, one or more phototransistors, one or more photo gates, one or more pinned photodiodes (PPDs), or a combination thereof, but the present disclosure is not limited thereto.

The first to fourth transfer transistors TX1 to TX4 may be coupled to the first to fourth photoelectric conversion elements PD1 to PD4, respectively. The first to fourth transfer transistors TX1 to TX4 may transfer the charges generated and accumulated in the first to fourth photoelectric conversion elements PD1 to PD4, respectively, to the first to fourth floating diffusion regions FD1 to FD4, respectively. The first to fourth floating diffusion regions FD1 to FD4 may be regions that convert charges into voltage. The first to fourth floating diffusion regions FD1 to FD4 may cumulatively store charges due to parasitic capacitance. The first to fourth transfer transistors TX1 to TX4 may be driven by a predetermined bias (e.g., transfer signal). For example, based on a transfer signal, the first to fourth transfer transistors TX1 to TX4 transfer the charges generated in the first to fourth photoelectric conversion elements PD1 to PD4, respectively, to the first to fourth floating diffusion regions FD1 to FD4, respectively.

In some embodiments, the first to fourth floating diffusion regions FD1 to FD4 are connected in common to a common node ND. The unit pixel group PG may include a common node ND sharing the first to fourth floating diffusion regions FD1 to FD4.

The drive transistor DX may be provided as a source follower buffer amplifier. The drive transistor DX may amplify the change in the electrical potential of the common node ND and output it to an output line V_{OUT}. When the drive transistor DX is turned on, a predetermined electrical potential (e.g., a power supply voltage V_{DD}) provided to the drain of the drive transistor DX may be transmitted to the drain region of the select transistor SX.

The select transistor SX may select the unit pixel group PG to be read on a row-by-row basis. The select transistor SX may be driven by a predetermined bias (e.g., row select signal) applied to a select line.

The reset transistor RX may periodically reset the first to fourth floating diffusion regions FD1 to FD4. The reset transistor RX may be driven by a predetermined bias (e.g., reset signal) applied to the reset line. When the reset transistor RX is turned on by the reset signal, a predetermined electrical potential (e.g., V_{DD}) provided to the drain of the reset transistor RX may be transmitted to the common node ND, resetting the first to fourth floating diffusion regions FD1 to FD4.

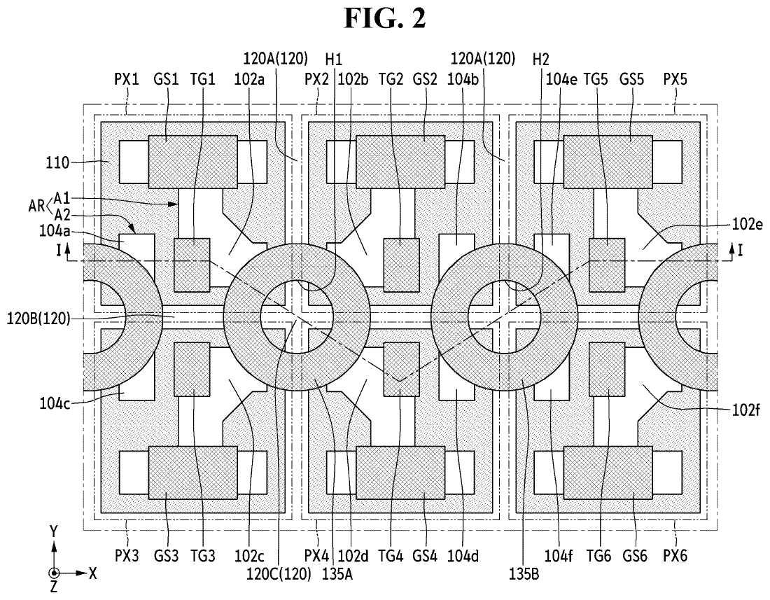

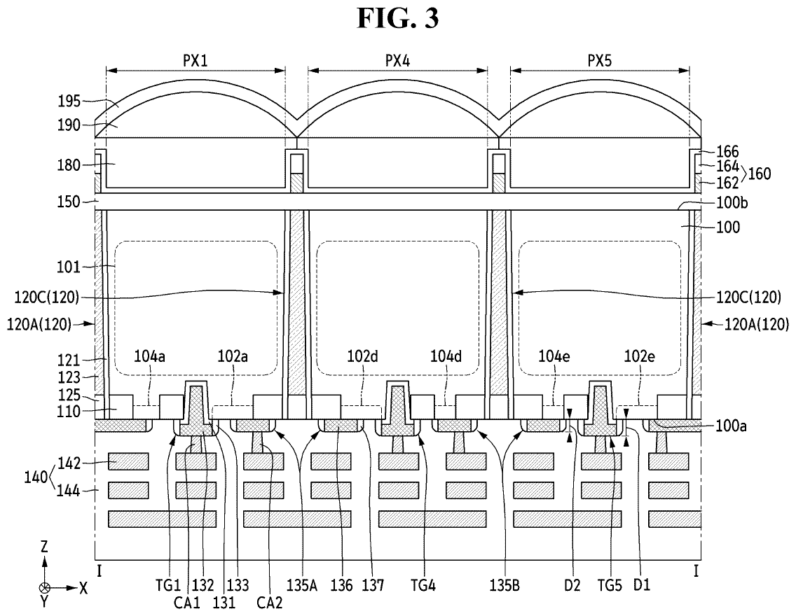

FIG. 2 is an exemplary plan view illustrating a pixel array of the image sensor, according to some embodiments of the present disclosure. FIG. 3 is an exemplary cross-sectional view taken along line I-I of FIG. 2, according to some embodiments of the present disclosure.

Referring to FIGS. 1 to 3, in some embodiments, the image sensor includes a first substrate 100, photoelectric conversion regions 101, element isolation patterns 110, a pixel isolation pattern 120, first to sixth gate structures GS1 to GS6, first to sixth transfer gate structures TG1 to TG6, a first pad structure 135A, a second pad structure 135B, first wiring structures 140, a surface insulating film 150, grid patterns 160, color filters 180, and micro lenses 190.

The first substrate 100 may be a semiconductor substrate. For example, the first substrate 100 includes bulk silicon, silicon-on-insulator (SOI), or the like. The first substrate 100 may be a silicon substrate or may include other materials, such as silicon-germanium (SiGe), indium antimonide, a lead telluride compound, indium arsenide, indium phosphide, gallium arsenide, or gallium antimonide. The first substrate 100 may include an epitaxial layer formed on a base substrate.

The first substrate 100 may include a first surface 100a and a second surface 100b that are opposite to each other. The first surface 100a may also be referred to as the front side of the first substrate 100, and the second surface 100b may also be referred to as the back side of the first substrate 100. The second surface 100b of the first substrate 100 may be a light-receiving surface (e.g., the image sensor may be a back-side-illuminated (BSI) image sensor).

In some embodiments, the first substrate 100 includes one or more impurities (e.g., dopants) of a first conductivity type. The first conductivity type will hereinafter be described as being, for example, p-type, but the present disclosure is not limited thereto. Alternatively, the first conductivity type may also be n-type.

A plurality of unit pixels (PX1 to PX6) may be formed in the first substrate 100. The unit pixels (PX1 to PX6) may be arranged two-dimensionally (e.g., in a matrix form) along a horizontal plane (e.g., an XY plane including a first direction X and a second direction Y). The unit pixels (PX1 to PX6) may include a first unit pixel PX1, a second unit pixel PX2, a third unit pixel PX3, and a fourth unit pixel PX4, which are adjacent to one another. The second unit pixel PX2 may be adjacent to the first unit pixel PX1 in the first direction X. The third unit pixel PX3 may be adjacent to the first unit pixel PX1 in the second direction Y. The fourth unit pixel PX4 may be adjacent to the second unit pixel PX2 in the second direction Y and adjacent to the third unit pixel PX3 in the first direction X. The fourth unit pixel PX4 may be adjacent to the first unit pixel PX1 in a direction that is diagonal with respect to the first and second directions X and Y.

The unit pixels (PX1 to PX6) may further include a fifth unit pixel PX5 and a sixth unit pixel PX6 that are adjacent to the second unit pixel PX2 and the fourth unit pixel PX4, respectively. The fifth unit pixel PX5 may be adjacent to the second unit pixel PX2 in the first direction X. The second unit pixel PX2 may be interposed between the first and fifth unit pixels PX1 and PX5. The sixth unit pixel PX6 may be adjacent to the fourth unit pixel PX4 in the first direction X and adjacent to the fifth unit pixel PX5 in the second direction Y. The sixth unit pixel PX6 may be adjacent to the second unit pixel PX2 in a direction that is diagonal with respect to the first and second directions X and Y.

The photoelectric conversion regions 101 may be formed in the first substrate 100. The photoelectric conversion regions 101 may be formed within the respective unit pixels (PX1 to PX6) arranged in the first substrate 100. For example, the photoelectric conversion regions 101 corresponding to the respective unit pixels (PX1 to PX6) are arranged two-dimensionally (e.g., in a matrix form) within the first substrate 100.

The photoelectric conversion regions 101 may have a second conductivity type different from the first conductivity type. For example, the photoelectric conversion regions 101 are be formed by ion-implanting n-type impurities into the p-type first substrate 100. The photoelectric conversion regions 101 and their surrounding regions of the first substrate 100 may be provided as the photoelectric conversion elements PD in FIG. 1.

The element isolation patterns 110 may be formed in the first substrate 100. The element isolation patterns 110 may be adjacent to (or in contact with) the first surface 100a of the first substrate 100. The element isolation patterns 110 may define active regions AR within the respective unit pixels (PX1 to PX6) adjacent to the first surface 100a. For example, shallow trenches (hereinafter referred to as element isolation trenches) extending from the first surface 100a to define the active regions AR are formed in the first substrate 100. The element isolation patterns 110 may fill at least parts of the element isolation trenches.

The element isolation patterns 110 may include an insulating material, such as silicon oxide, silicon nitride, silicon oxynitride, or a combination thereof, but the present disclosure is not limited thereto. For example, the element isolation patterns 110 is provided in the form of a silicon oxide film. The element isolation patterns 110 are illustrated as single layers, but the present disclosure is not limited thereto. The element isolation patterns 110 may be multilayered.

In some embodiments, the active regions AR of the unit pixels (PX1 to PX6) include first active patterns A1 and second active patterns A2. The first active patterns A1 and the second active patterns A2 may be separated by the element isolation patterns 110. The shapes, sizes, numbers, and arrangements of the first active patterns A1 and the second active patterns A2 are merely exemplary and are not particularly limited.

In some embodiments, first to sixth impurity regions 102a to 102f may be formed in the first active patterns A1 of the first to sixth unit pixels PX1 to PX6, respectively. The first to sixth impurity regions 102a to 102f may each have the second conductivity type. For example, the first to sixth impurity regions 102a to 102f are formed by ion-implanting n-type impurities into the first active patterns A1.

In some embodiments, seventh to twelfth impurity regions 104a to 104f may be formed in the second active patterns A2 of the first to sixth unit pixels PX1 to PX6, respectively. The seventh to twelfth impurity regions 104a to 104f may each have the first conductivity type. For example, the seventh to twelfth impurity regions 104a to 104f may be formed by ion-implanting p-type impurities into the second active patterns A2. The seventh to twelfth impurity regions 104a to 104f may serve as ground regions to which a ground voltage is applied.

The pixel isolation pattern 120 may be formed in the first substrate 100. The pixel isolation pattern 120 may define the unit pixels (PX1 to PX6) within the first substrate 100. For example, a deep trench (hereinafter referred to as a pixel isolation trench) defining the unit pixels (PX1 to PX6) are formed in the first substrate 100. As illustrated in the plan view of FIG. 2, the pixel isolation trench (corresponds to pixel isolation pattern 120) may be formed in a grid shape (e.g., in the XY plane) to surround each of the unit pixels (PX1 to PX6). The pixel isolation pattern 120 may fill at least part of the pixel isolation trench.

The pixel isolation pattern 120 may prevent photocharges generated in each particular unit pixel (e.g., the first unit pixel PX1) from crossing into neighboring unit pixels (e.g., the second to fourth unit pixels PX2 to PX4) due to random drift. The pixel isolation pattern 120 may also mitigate optical crosstalk by ensuring that light incident on each particular unit pixel (e.g., the first unit pixel PX1) does not influence neighboring unit pixels (e.g., the second to fourth unit pixels PX2 to PX4).

In some embodiments, the pixel isolation pattern 120 includes first isolation portions 120A, second isolation portions 120B, and crossing portions 120C, which are connected to one another in a plan view.

The first isolation portions 120A may extend longitudinally along the second direction Y. The first isolation portions 120A may separate unit pixels (e.g., the first and second unit pixels PX1 and PX2) that are adjacent to each other in the first direction X. The second isolation portions 120B may extend longitudinally along the first direction X. The second isolation portion 120B may separate unit pixels (e.g., the first and third unit pixels PX1 and PX3) that are adjacent to each other in the second direction Y. The crossing portions 120C may be disposed in the regions where the first isolation portions 120A and the second isolation portions 120B intersect. The crossing portions 120C may separate unit pixels (e.g., the first and fourth unit pixels PX1 and PX4) that are adjacent to each other in the direction that is diagonal with respect to the first and second directions X and Y.

In some embodiments, the width of the pixel isolation pattern 120 decreases from the first surface 100a toward the second surface 100b due to the etching process. The etching process for forming the pixel isolation pattern 120 may be performed toward the first surface 100a of the first substrate 100. Here, the width of the pixel isolation pattern 120 refers to the width measured along the horizontal plane (e.g., the XY plane). For example, the width of the pixel isolation pattern 120 refers to the width of the first isolation portions 120A measured in the first direction X and/or the width of the second isolation portions 120B measured in the second direction Y. The pixel isolation pattern 120 may be a frontside deep trench isolation (FDTI) formed by performing a deep trench isolation (DTI) process on the front side (e.g., the first surface 100a) of the first substrate 100.

At the first surface 100a, the width of the pixel isolation pattern 120 may be about 50 nm to about 200 nm, about 80 nm to about 150 nm, or about 100 nm to about 140 nm, but the present disclosure is not limited thereto.

In some embodiments, the pixel isolation pattern 120 penetrates the first substrate 100. The pixel isolation pattern 120 may be adjacent to (e.g., be in contact with or pass through) both the first and second surfaces 100a and 100b. The pixel isolation pattern 120 may include a liner insulating film 121, a gap-fill conductive film 123, and a buried insulating film 125. The liner insulating film 121 may be stacked on the inner walls of the first substrate 100. The liner insulating film 121 may be interposed between the first substrate 100 and the gap-fill conductive film 123. For example, the liner insulating film 121 extends conformally along the profile of the inner walls of the first substrate 100.

The liner insulating film 121 may include an insulating material such as silicon oxide, silicon nitride, silicon oxynitride, silicon carbonitride, silicon oxycarbonitride, or a combination thereof, but the present disclosure is not limited thereto. The liner insulating film 121 is illustrated as a single layer, but the present disclosure is not limited thereto. The liner insulating film 121 may be multilayered. The element isolation patterns 110 and the liner insulating film 121 are illustrated as having distinct boundaries therebetween, but the present disclosure is not limited thereto. There may be no distinct boundaries that separate the element isolation patterns 110 and the liner insulating film 121. For example, when the element isolation patterns 110 and the liner insulating film 121 include the same material (e.g., silicon oxide), the boundaries between the element isolation patterns 110 and the liner insulating film 121 are indistinguishable.

The gap-fill conductive film 123 may be stacked on the liner insulating film 121. The gap-fill conductive film 123 may fill at least part of the pixel isolation pattern 120 that remains after the filling of the liner insulating film 121. The gap-fill conductive film 123 may be spaced apart from the first surface 100a and may be in contact with the second surface 100b. The gap-fill conductive film 123 may include a conductive material, such as undoped polysilicon, undoped SiGe, doped polysilicon, doped SiGe, or a metal film, but the present disclosure is not limited thereto. For example, the gap-fill conductive film 123 includes a polysilicon film doped with p-type impurities (e.g., boron (B)) or n-type impurities (e.g., phosphorus (P)).

In some embodiments, a bias signal (e.g., a negative bias voltage) is applied to the gap-fill conductive film 123. The gap-fill conductive film 123 may thusly adjust electrical characteristics in the image sensor (e.g., capture holes that may exist on the surface of the first substrate 100 adjacent to the pixel isolation pattern 120), thereby improving the dark current characteristics of the image sensor according to some embodiments of the present disclosure.

in some embodiments, the buried insulating film 125 is stacked on the liner insulating film 121 and the gap-fill conductive film 123. The gap-fill conductive film 123 may be spaced apart from the first surface 100a by the buried insulating film 125. Part of the liner insulating film 121 may be interposed between the element isolation patterns 110 and the buried insulating film 125. The depth at which the buried insulating film 125 is formed is illustrated as being the same as the depth at which the element isolation patterns 110 are formed, based on the first surface 100a, but the present disclosure is not limited thereto. The depth at which the buried insulating film 125 is formed may differ from the depth at which the element isolation patterns 110 are formed.

The buried insulating film 125 may include an insulating material, such as silicon oxide, silicon nitride, silicon oxynitride, or a combination thereof, but the present disclosure is not limited thereto. The buried insulating film 125 is illustrated as being a single layer, but the present disclosure is not limited thereto. The buried insulating film 125 may be multilayered. The liner insulating film 121 and the buried insulating film 125 are illustrated as having a distinct boundary therebetween, but the present disclosure is not limited thereto. There may be no distinct boundary that separates the liner insulating film 121 and the buried insulating film 125. For example, when the liner insulating film 121 and the buried insulating film 125 include the same material (e.g., silicon oxide), the boundary between the liner insulating film 121 and the buried insulating film 125 are indistinguishable.

In some embodiments, the first to sixth gate structures GS1 to GS6 each are disposed on the first surface 100a of the first substrate 100. The first to sixth gate structures GS1 to GS6 may be disposed on the first active patterns A1 of the first to sixth unit pixels PX1 to PX6, respectively. The shapes, sizes, numbers, and arrangements of the first to sixth gate structures GS1 to GS6 are merely exemplary and are not particularly limited.

The first to sixth gate structures GS1 to GS6 may each include various transistors for processing electrical signals generated from the first to sixth unit pixels PX1 to PX6, respectively. For example, each of the first to sixth gate structures GS1 to GS6 may be provided as the gate of at least one of the reset transistor RX, the drive transistor DX, and the select transistor SX described above with reference to FIG. 1.

The first to sixth transfer gate structures TG1 to TG6 may each be disposed on the first surface 100a of the first substrate 100. The first to sixth transfer gate structures TG1 to TG6 may be spaced apart from the first to sixth gate structures GS1 to GS6, respectively. The first to sixth transfer gate structures TG1 to TG6 may be adjacent to the first to sixth impurity regions 102a to 102f, respectively. For example, the first to sixth transfer gate structures TG1 to TG6 may be respectively disposed on the first active patterns A1 adjacent to the first to sixth impurity regions 102a to 102f.

In some embodiments, the first to sixth transfer gate structures TG1 to TG6 may each include a vertical transfer gate. For example, parts of the first to sixth transfer gate structures TG1 to TG6 may protrude into the first substrate 100 toward the photoelectric conversion regions 101. The first to sixth transfer gate structures TG1 to TG6 may contribute to the high integration of the image sensor according to some embodiments of the present disclosure by reducing the area of the first to sixth unit pixels PX1 to PX6.

In some embodiments, each of the first to sixth gate structures GS1 to GS6 and each of the first to sixth transfer gate structures TG1 to TG6 may include a gate dielectric film 131, a gate electrode film 132, and gate spacers 133. The gate dielectric film 131 may be interposed between the first substrate 100 and the gate electrode film 132. The gate dielectric film 131 may include a dielectric material such as silicon oxide, silicon oxynitride, silicon nitride, or at least one high-k material with a greater dielectric constant than silicon oxide. Examples of the high-k material include hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanate, barium titanate, strontium titanate, yttrium oxide, aluminum oxide, lead scandium tantalate, lead zinc niobate, and a combination thereof, but the present disclosure is not limited thereto.

The gate electrode film 132 may be stacked on the gate dielectric film 131. The gate electrode film 132 may include a conductive material such as a metal film, a metal silicide film, an undoped polysilicon film, an undoped SiGe film, a doped polysilicon film, or a doped SiGe film, but the present disclosure is not limited thereto. For example, the gate electrode film 132 includes a polysilicon film doped with n-type impurities.

The gate spacers 133 may extend along the side surfaces of the gate electrode film 132. The gate spacers 133 may include an insulating material such as silicon oxide, silicon nitride, silicon oxynitride, silicon oxycarbide, boron nitride, boron carbon nitride, silicon oxycarbide nitride, or a combination thereof, but the present disclosure is not limited thereto.

The first pad structure 135A may be disposed on the first surface 100a of the first substrate 100. The first pad structure 135A may be spaced apart from the first to sixth gate structures GS1 to GS6 and the first to sixth transfer gate structures TG1 to TG6. The first pad structure 135A may electrically connect the first active patterns A1 of the first to fourth unit pixels PX1 to PX4. The first pad structure 135A may electrically connect the first to fourth impurity regions 102a to 102d. For example, the first pad structure 135A are in contact with at least parts of the first to fourth impurity regions 102a to 102d.

The first to fourth impurity regions 102a to 102d connected together by the first pad structure 135A may be provided as the first to fourth floating diffusion regions FD1 to FD4 described with reference to FIG. 1. The first pad structure 135A may be provided as the common node ND described with reference to FIG. 1. The first to fourth unit pixels PX1 to PX4 may form the unit pixel group PG described with reference to FIG. 1.

The first pad structure 135A may overlap with parts of the first isolation portions 120A and parts of the second isolation portions 120B in a third direction Z. Here, the term “overlap” may refer to an apparent overlap of structures from a point of view along a vertical direction (e.g., third direction Z—a viewing axis that intersects the first surface 100a of the first substrate 100). The first pad structure 135A may extend across the first to fourth unit pixels PX1 to PX4, thereby connecting the first to fourth impurity regions 102a to 102d.

The shape of first pad structure 135A may be such that the first pad structure 135A avoids overlapping the crossing portions 120C of the pixel isolation pattern 120. For example, as illustrated in FIG. 2, the first pad structure 135A includes a first hole H1. The first hole H1 may expose the crossing portion 120C between the first and fourth unit pixels PX1 and PX4. The first hole H1 may define a contact avoidance region of the first pad structure 135A, which allows the first pad structure 135A to avoid contact with the crossing portion 120C. The contact avoidance region provides for electrical isolation between the first pad structure 135A and the crossing portion 120C. It should be noted that although a circular hole is illustrated in FIG. 2, this is merely exemplary. In general, the first hole H1 may have any suitable shape. The first pad structure 135A may form a closed loop extending continuously across the first to fourth unit pixels PX1 to PX4.

In some embodiments, the first hole H1 exposes the crossing portion 120C between the first and fourth unit pixels PX1 and PX4. The width (e.g., diameter) of the first hole H1 may be greater than the width of the pixel isolation pattern 120. Here, the width of the first hole H1 may refer to the maximum width measured along the horizontal plane (e.g., the XY plane). The width of the first hole H1 may be about 100 nm to about 500 nm, about 150 nm to about 350 nm, or about 200 nm to about 300 nm, but the present disclosure is not limited thereto.

The first hole H1 may expose parts of the first isolation portions 120A adjacent to the crossing portion 120C, parts of the second isolation portions 120B adjacent to the crossing portion 120C, and/or parts of the element isolation patterns 110 adjacent to the crossing portion 120C.

In some embodiments, the perimeter of the first pad structure 135A may be circular in a plan view. The perimeter of the first pad structure 135A is illustrated as being completely circular, but the present disclosure is not limited thereto. The perimeter of the first pad structure 135A may be elliptical. A shape of the first pad structure 135A may be annular.

The second pad structure 135B may be disposed on the first surface 100a of the first substrate 100. The second pad structure 135B may be spaced apart from the first to sixth gate structures GS1 to GS6, the first to sixth transfer gate structures TG1 to TG6, and the first pad structure 135A.

The second pad structure 135B may electrically connect the second active patterns A2 of the second and fourth to sixth unit pixels PX2 and PX4 to PX6. The second pad structure 135B may electrically connect the eighth impurity region 104b and the tenth to twelfth impurity regions 104d to 104f. The second pad structure 135B may be in contact with at least parts of the eighth impurity region 104b and tenth to twelfth impurity regions 104d to 104f.

The second pad structure 135B may overlap with parts of the first isolation portions 120A and parts of the second isolation portions 120B in the third direction Z. Here, the term “overlap” may refer to an apparent overlap of structures from a point of view along the vertical direction (e.g., third direction Z—a viewing axis that intersects the first surface 100a of the first substrate 100). The second pad structure 135B may extend across the second and fourth to sixth unit pixels PX2 and PX4 to PX6, thereby connecting the eighth impurity region 104b and tenth to twelfth impurity regions 104d to 104f.

The shape of second pad structure 135B may be such that the second pad structure 135B avoids overlapping the crossing portions 120C of the pixel isolation pattern 120. For example, as illustrated in FIG. 2, the second pad structure 135B includes a second hole H2. The second hole H2 may expose the crossing portion 120C between the second unit pixel PX2 and the sixth unit pixel PX6. The second hole H2 may define a contact avoidance region of second pad structure 135B, which allows second pad structure 135B to avoid contact with the crossing portion 120C. The second pad structure 135B may form a closed loop extending continuously across the second and fourth to sixth unit pixels PX2 and PX4 to PX6.

In some embodiments, the second hole H2 exposes the crossing portion 120C between the second unit pixel PX2 and the sixth unit pixel PX6. For example, the width (e.g., diameter) of the second hole H2 may be greater than the width of the pixel isolation pattern 120. Here, the width of the second hole H2 may refer to the maximum width measured along the horizontal plane (e.g., the XY plane). The width of the second hole H2 may be about 100 nm to about 500 nm, about 150 nm to about 350 nm, or about 200 nm to about 300 nm, but the present disclosure is not limited thereto.

The second hole H2 may expose parts of the first isolation portions 120A adjacent to the crossing portion 120C, parts of the second isolation portions 120B adjacent to the crossing portion 120C, and/or parts of the element isolation patterns 110 adjacent to the crossing portion 120C.

In some embodiments, the perimeter of the second pad structure 135B may be circular in a plan view. The perimeter of the second pad structure 135B is illustrated as being completely circular, but the present disclosure is not limited thereto. Alternatively, the perimeter of the second pad structure 135B may be elliptical. A shape of the second pad structure 135B may be annular.

The first and second pad structures 135A and 135B are illustrated as having the same shape and size, but the present disclosure is not limited thereto. The shapes, sizes, and arrangements of the first and second pad structures 135A and 135B are merely exemplary and are not particularly limited.

In some embodiments, each of the first and second pad structures 135A and 135B may include a pad conductive film 136 and pad spacers 137. The pad conductive film 136 may be stacked on the active regions AR, the element isolation patterns 110, and the pixel isolation pattern 120. The pad conductive film 136 may contact the first to fourth impurity regions 102a to 102d. The first to fourth impurity regions 102a to 102d may be connected in common by the pad conductive film 136.

The pad conductive film 136 may include a conductive material such as a metal film, a metal silicide film, an undoped polysilicon film, an undoped SiGe film, a doped polysilicon film, or a doped SiGe film, but the present disclosure is not limited thereto. For example, the pad conductive film 136 includes a polysilicon film doped with n-type impurities.

In some embodiments, the pad conductive film 136 is formed at the same level as the gate electrode film 132. Forming structures “at the same level” may refer to forming the structures by the same manufacturing process (e.g., a level may be a given layer of a layered manufacturing processes). For example, the pad conductive film 136 includes the same conductive material (or the same material composition) as the gate electrode film 132. The gate electrode film 132 and the pad conductive film 136 may both include a polysilicon film doped with n-type impurities.

In some embodiments, with respect to the first surface 100a, a height D1 of the gate electrode film 132 may be greater than a height D2 of the pad conductive film 136. The difference between the heights D1 and D2 (e.g., D1−D2), may be the same as the thickness of the gate dielectric film 131. It is to be appreciated that the term “same” as used herein is not limited to exact identity and may include minor differences that arise due to process margins.

The width of the pad conductive film 136 may be about 50 nm to about 200 nm, about 70 nm to about 150 nm, or about 80 nm to about 120 nm, but the present disclosure is not limited thereto. Here, the width of the pad conductive film 136 may refer to the width measured in a direction perpendicular to the extension direction of the pad conductive film 136. For example, in FIG. 3, the width of the pad conductive film 136 refers to the width measured in the first direction X.

In some embodiments, the pad spacers 137 extend along the side surfaces of the pad conductive film 136. The pad spacers 137 may include an insulating material, such as silicon oxide, silicon nitride, silicon oxynitride, silicon oxycarbide, boron nitride, boron carbonitride, silicon oxycarbonitride, or a combination thereof, but the present disclosure is not limited thereto. The pad spacers 137 may be formed at the same level as the gate spacers 133. For example, the pad spacers 137 include the same insulating material (or the same material composition) as the gate spacers 133.

The first wiring structure 140 may be formed on the first surface 100a of the first substrate 100. The first wiring structure 140 may include a plurality of wiring patterns. For example, the first wiring structure 140 includes a first interlayer insulating film 144 on the first surface 100a and first wiring patterns 142 in the first interlayer insulating film 144. In FIG. 3, the number of layers and the arrangement of the first wiring patterns 142 are merely exemplary and are not particularly limited.

The first wiring structure 140 may be electrically connected to the first to sixth gate structures GS1 to GS6, the first to sixth transfer gate structures TG1 to TG6, the first pad structure 135A, and/or the second pad structure 135B. For example, a first contact CA1, which extends in the third direction Z, is formed to connect at least one of the first to sixth transfer gate structures TG1 to TG6 to the first wiring patterns 142. A second contact CA2, which extends in the third direction Z, may be formed to connect one of the first and second pad structures 135A and 135B to the first wiring patterns 142. The first wiring structure 140 may send and receive electrical signals to and from the unit pixels (PX1 to PX6) to the first contact CA1 and/or the second contact CA2. The first and second contacts CA1 and CA2 may each include a conductive material, such as a metal film or a metal silicide film, but the present disclosure is not limited thereto.

In some embodiments, the surface insulating film 150 is formed on the second surface 100b of the first substrate 100. The surface insulating film 150 may extend conformally along the second surface 100b of the first substrate 100. The surface insulating film 150 may include an insulating material, such as silicon oxide, silicon nitride, silicon oxynitride, aluminum oxide, hafnium oxide, or a combination thereof, but the present disclosure is not limited thereto.

The surface insulating film 150 may serve as an anti-reflection film to prevent reflection of light incident on the light-receiving surface, which is the second surface 100b. This can enhance the light-receiving efficiency of the photoelectric conversion regions 101. Alternatively, the surface insulating film 150 may serve as a planarization film, contributing to the formation of the color filters 180 and the micro lenses 190 at a uniform height.

In some embodiments, the surface insulating film 150 may be multilayered. For example, the surface insulating film 150 may include an aluminum oxide film, a hafnium oxide film, a silicon oxide film, a silicon nitride film, and a hafnium oxide film that are sequentially stacked on the second surface 100b of the first substrate 100.

The grid pattern 160 may be formed on the surface insulating film 150. The grid pattern 160 may be formed in a lattice shape in a plan view (e.g., across the XY plane). For example, the grid pattern 160 is disposed to overlap with at least part of the pixel isolation pattern 120 in the third direction Z. The grid pattern 160 may include a first grid film 162 and a second grid film 164. The first and second grid films 162 and 164 may be sequentially stacked on the surface insulating film 150. The first grid film 162 may include, for example, titanium (Ti), titanium nitride (TiN), tantalum (Ta), tantalum nitride (TaN), tungsten (W), aluminum (Al), copper (Cu), or a combination thereof, but the present disclosure is not limited thereto. The first grid film 162 can effectively prevent charges generated by electrostatic discharge (ESD) from accumulating on the surface (e.g., the second surface 100b) of the first substrate 100, thereby effectively preventing an ESD bruise defect.

The second grid film 164 may include a low refractive index material having a lower refractive index than silicon (Si). For example, the second grid film 164 may include silicon oxide, aluminum oxide, tantalum oxide, or a combination thereof, but the present disclosure is not limited thereto. The second grid film 164 can enhance the light-gathering efficiency of the unit pixels (PX1 to PX6) by refracting or reflecting light obliquely incident on the light-receiving surface, which is the second surface 100b.

The first protective film 166 may be formed on the surface insulating film 150 and the grid pattern 160. The first protective film 166 may extend conformally along the profiles of the surface insulating film 150 and the grid pattern 160. The first protective film 166 can prevent damage to the surface insulating film 150 and the grid pattern 160. The first protective film 166 may include, for example, aluminum oxide (AlO), but the present disclosure is not limited thereto.

The color filters 180 may be formed on the first protective film 166. The color filters 180 may have various colors according to their respective unit pixels (PX1 to PX6). For example, the color filters 180 may include a red color filter, a green color filter, a blue color filter, a yellow filter, a magenta filter, and a cyan filter, and may further include a white filter.

The micro lenses 190 may be formed on the color filters 180. The micro lenses 190 may have a convex shape and a predetermined curvature radius. Accordingly, the micro lenses 190 can concentrate light incident on the photoelectric conversion regions 101. The micro lenses 190 may include, for example, a light-transmitting resin, but the present disclosure is not limited thereto.

The second protective film 195 may be formed on the micro lenses 190. The second protective film 195 may extend along the surfaces of the micro lenses 190. The second protective film 195 may include an inorganic oxide film, such as silicon oxide, titanium oxide, zirconium oxide, or hafnium oxide, but the present disclosure is not limited thereto. For example, the second protective film 195 includes a low-temperature oxide (LTO).

The second protective film 195 may protect the micro lenses 190 from external damage. For example, the second protective film 195 having an inorganic oxide film protect the micro lenses 190 having an organic material. Additionally, the second protective film 195 may improve the light-gathering efficiency of the micro lens 190, thereby enhancing the quality of the image sensor. The second protective film 195 may fill the spaces between the micro lenses 190, thereby reducing the reflection, refraction, and scattering of incident light that arrive in the spaces between the micro lenses 190.

To improve the integration of an image sensor, a unit pixel group may be arranged, in which a plurality of unit pixels share one floating diffusion region. For example, a plurality of floating diffusion regions formed in the plurality of unit pixels, respectively, are connected to one another to a plurality of metal contacts, respectively. To reduce leakage current caused by the metal contacts, a polysilicon pad extending across the plurality of unit pixels and directly connecting the plurality of floating diffusion regions may be provided. However, the polysilicon pad may cause a short with a pixel isolation pattern separating the plurality of unit pixels, which degrades the performance of the image sensor. For example, pixel isolation patterns include a conductive material (e.g., a polysilicon film doped with impurities) as a way to improve dark current characteristics. However, such a pixel isolation pattern may cause a short the polysilicon pad in the overlapping region, thereby reducing the conversion gain of the image sensor.

To address the above noted issues, in some embodiments, the image sensor may provide the first pad structure 135A with a reduced overlapping area with the pixel isolation pattern 120. Specifically, as described above, the first pad structure 135A (having the first hole H1) may form a closed loop continuously extending across the first to fourth unit pixels PX1 to PX4. By exposing the crossing portions 120C of the pixel isolation pattern 120 in a plan view, the first pad structure 135A can reduce the overlapping area with the gap-fill conductive film 123. This can improve the leakage current and conversion gain, thereby providing an image sensor with enhanced performance.

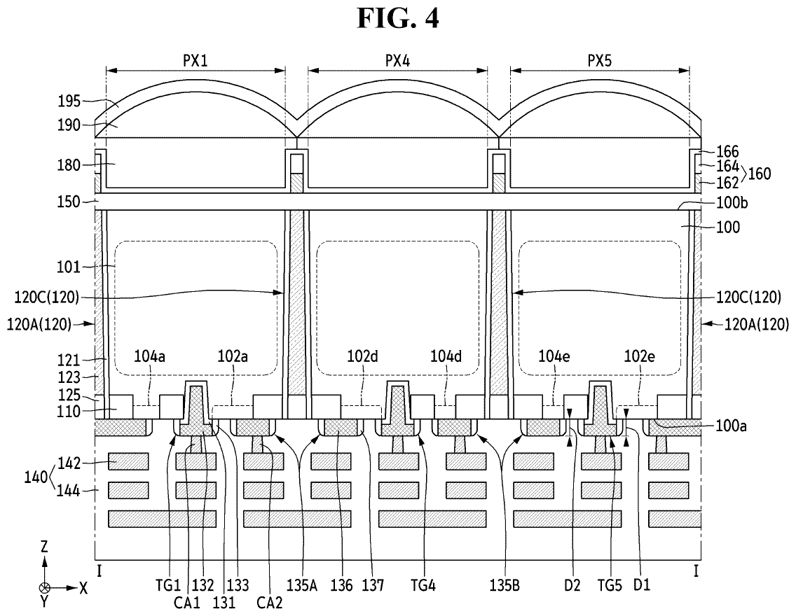

FIGS. 4 to 9 are other exemplary cross-sectional views of the image sensor, according to some embodiments of the present disclosure. For brevity, features in common with those described above with reference to FIGS. 1 to 3 may be omitted or provided a shortened description.

Referring to FIGS. 1, 2, and 4, in some embodiments, the height D1 of the gate electrode film 132 may be equal to or less than the height D2 of the pad conductive film 136, with respect to the first surface 100a. The pad conductive film 136 may be formed at a different level from the gate electrode film 132. The pad conductive film 136 may include a different conductive material from the gate electrode film 132.

Referring to FIGS. 1, 2, and 5, in some embodiments, the first pad structure 135A and/or the second pad structure 135B may omit the pad spacers 137 in FIG. 3. The pad conductive film 136 may be formed at a different level from the gate electrode film 132. The pad conductive film 136 may include a different conductive material from the gate electrode film 132.

Referring to FIGS. 1, 2, and 6, in some embodiments, part of the first pad structure 135A and/or part of the second pad structure 135B overlaps with the first to sixth gate structures GS1 to GS6 and/or the first to sixth transfer gate structures TG1 to TG6. The first to sixth gate structures GS1 to GS6 and the first to sixth transfer gate structures TG1 to TG6 may each further include a gate capping film 134. The gate capping film 134 may extend along the surface (e.g., the upper surface) of the gate electrode film 132 exposed by the gate spacers 133. The gate capping film 134 may further extend along the gate spacers 133. Part of the pad conductive film 136 may be formed on the gate capping film 134. For example, part of the pad conductive film 136 extends conformally along the gate capping film 134. The pad conductive film 136 may be separated from the gate electrode film 132 by the gate capping film 134.

Referring to FIGS. 1, 2, and 7, in some embodiments, part of the first pad structure 135A does not contact the first to fourth impurity regions 102a to 102d, and part of the second pad structure 135B does not contact the eighth impurity region 104b and tenth to twelfth impurity regions 104d to 104f.

Part of the first pad structure 135A may contact areas of the first active patterns A1 where the first to fourth impurity regions 102a to 102d are not formed. Part of the second pad structure 135B may contact areas of the second active pattern A2 where the eighth impurity region 104b and tenth to twelfth impurity regions 104d to 104f are not formed.

Referring to FIGS. 1, 2, and 8, in some embodiments, the pixel isolation pattern 120 further includes a liner conductive film 122 and a gap-fill insulating film 124. The liner conductive film 122 may be stacked on the liner insulating film 121. The liner conductive film 122 may extend along the inner surface of the liner insulating film 121. The liner conductive film 122 may be interposed between the liner insulating film 121 and the gap-fill conductive film 123, and between the liner insulating film 121 and the gap-fill insulating film 124. The liner insulating film 121 may extend across the first isolation portions 120A, the second isolation portions 120B, and the crossing portions 120C.

The liner conductive film 122 may include a conductive material such as an undoped polysilicon film, an undoped SiGe film, a doped polysilicon film, a doped SiGe film, or a metal film, but the present disclosure is not limited thereto. For example, the gap-fill conductive film 123 includes a polysilicon film doped with p-type impurities (e.g., B) or n-type impurities (e.g., P). The liner conductive film 122 and the gap-fill conductive film 123 are illustrated as having a distinct boundary therebetween, but the present disclosure is not limited thereto. There may be no distinct boundary that separates the liner conductive film 122 and the gap-fill conductive film 123.

The gap-fill insulating film 124 may be stacked on the liner conductive film 122. The gap-fill insulating film 124 may fill at least part of the pixel isolation pattern 120 that remains after the filling of the liner conductive film 122. The gap-fill insulating film 124 may be spaced apart from the first surface 100a and in contact with the second surface 100b.

The gap-fill insulating film 124 may include an insulating material such as silicon oxide, silicon nitride, silicon oxynitride, silicon oxycarbide, silicon oxycarbonitride, or a combination thereof, but the present disclosure is not limited thereto. The buried insulating film 125 and the gap-fill insulating film 124 are illustrated as having a distinct boundary therebetween, but the present disclosure is not limited thereto. There may be no distinct boundary that separates the buried insulating film 125 and the gap-fill insulating film 124.

In some embodiments, the gap-fill conductive film 123 is formed within the crossing portions 120C and not within the first isolation portions 120A and the second isolation portions 120B. The first isolation portions 120A and the second isolation portions 120B may each include the liner insulating film 121, the liner conductive film 122, the gap-fill insulating film 124, and the buried insulating film 125. The first isolation portions 120A and the second isolation portions 120B may omit the gap-fill conductive film 123.

The crossing portions 120C may each include the liner insulating film 121, the liner conductive film 122, the gap-fill conductive film 123, and the buried insulating film 125. The crossing portions 120C may omit the gap-fill insulating film 124. In this case, the overlapping area between the first pad structure 135A and/or the second pad structure 135B and the gap-fill conductive film 123 may be further reduced, providing an image sensor with further improved performance.

Referring to FIGS. 1, 2, and 9, in some embodiments, the image sensor may further include a backside isolation pattern 128. The backside isolation pattern 128 may contact the second surface 100b and may be spaced apart from the first surface 100a. The backside isolation pattern 128 may overlap with the pixel isolation pattern 120 in the third direction Z. For example, the backside isolation pattern 128 may be formed in a grid shape in a plan view (e.g., across the XY plane) to surround each of the unit pixels (PX1 to PX6) adjacent to the second surface 100b.

The pixel isolation pattern 120 and the backside isolation pattern 128 may penetrate the first substrate 100. For example, the pixel isolation pattern 120 may contact or pass through the first surface 100a and may be spaced apart from the second surface 100b. The backside isolation pattern 128 may contact one end of the pixel isolation pattern 120 that is spaced apart from the second surface 100b.

In some embodiments, the width of the backside isolation pattern 128 may decrease from the second surface 100b toward the first surface 100a due to the etching process for forming the backside isolation pattern 128 being performed toward the second surface 100b of the first substrate 100. Here, the width of the backside isolation pattern 128 refers to the width measured along the horizontal plane (e.g., the XY plane). For example, the backside isolation pattern 128 may be a backside deep trench isolation (BDTI) formed by performing a DTI process on the backside (e.g., the second surface 100b) of the first substrate 100.

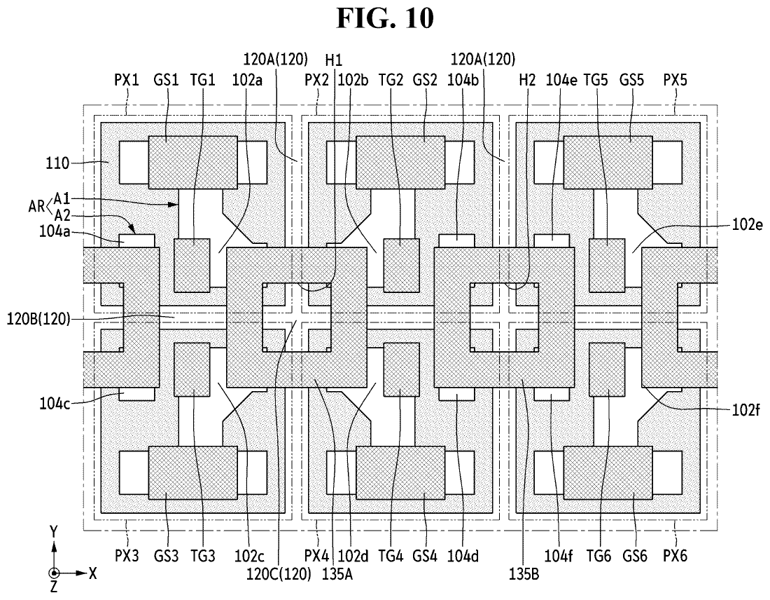

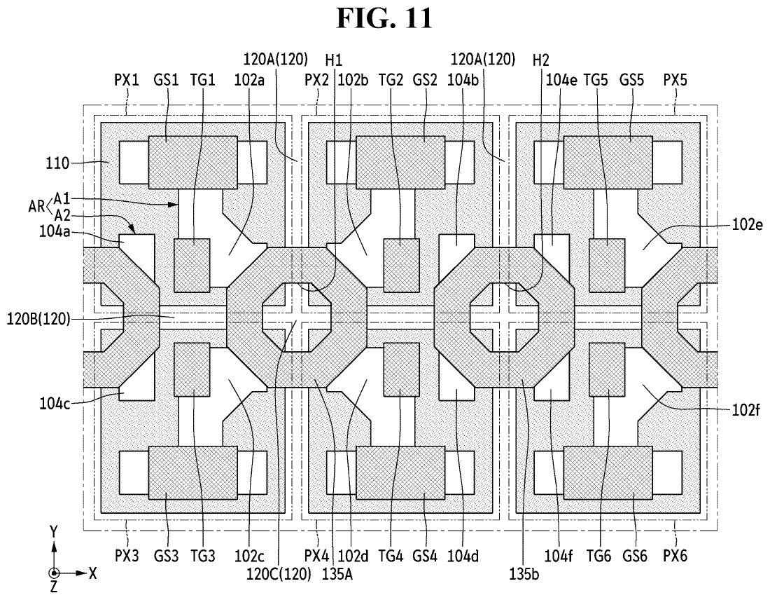

FIGS. 10 and 11 are other exemplary plan views of the image sensor, according to some embodiments of the present disclosure. For brevity, features in common with those described above with reference to FIGS. 1 to 9 may be omitted or provided a shortened description.

Referring to FIGS. 10 and 11, in some embodiments, the perimeter of the first pad structure 135A and/or the perimeter of the second pad structure 135B may be polygonal in a plan view. For example, as illustrated in FIG. 10, the perimeter of the first pad structure 135A and/or the perimeter of the second pad structure 135B is rectangular in a plan view. In another example, as illustrated in FIG. 11, the perimeter of the first pad structure 135A and/or the perimeter of the second pad structure 135B is octagonal in a plan view. The first pad structure 135A and the second pad structure 135B are illustrated as having the same shape and size, but the present disclosure is not limited thereto. The shapes, sizes, and arrangements of the first and second pad structures 135A and 135B are merely exemplary and are not particularly limited.

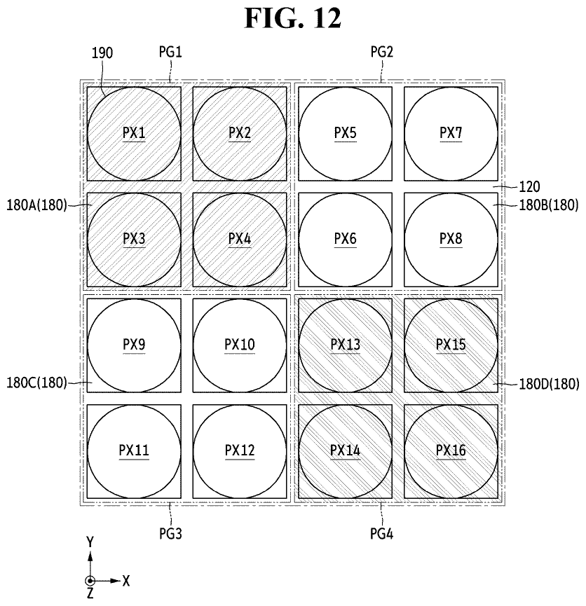

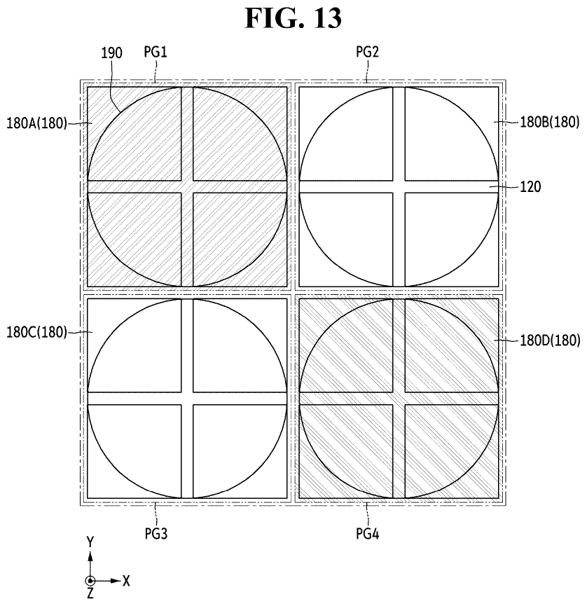

FIGS. 12 and 13 are various exemplary plan views of the pixel array of the image sensor, according to some embodiments of the present disclosure. For brevity, features in common with those described above with reference to FIGS. 1 to 11 may be omitted or provided a shortened description.

Referring to FIGS. 12 and 13, in some embodiments, the image sensor includes first to fourth pixel groups PG1 to PG4, which are adjacent to one another. The second pixel group PG2 may be adjacent to the first pixel group PG1 in the first direction X. The third pixel group PG3 may be adjacent to the first pixel group PG1 in the second direction Y. The fourth pixel group PG4 may be adjacent to the second pixel group PG2 in the second direction Y and adjacent to the third pixel group PG3 in the first direction X. The fourth pixel group PG4 may be adjacent to the first pixel group PG1 in the direction that is diagonal with respect to the first and second directions X and Y.

Each of the first to fourth pixel groups PG1 to PG4 may form the unit pixel group PG described above with reference to FIG. 1. For example, the first pixel group PG1 may include first to fourth unit pixels PX1 to PX4, which are as described above with reference to FIGS. 1 to 11. Fifth to eighth unit pixels PX5 to PX8 of the second pixel group PG2, ninth to twelfth unit pixels PX9 to PX12 of the third pixel group PG3, and thirteenth to sixteenth unit pixels PX13 to PX16 of the fourth pixel group PG4 may each correspond to the first to fourth unit pixels PX1 to PX4, respectively.

In some embodiments, the unit pixels included in each of the first to fourth pixel groups PG1 to PG4 may share a color filter of the same color. Adjacent pixel groups may have color filters of different colors. For example, the first to fourth pixel groups PG1 to PG4 includes color filters 180 arranged in a Bayer pattern. The first to fourth unit pixels PX1 to PX4 of the first pixel group PG1 may overlap with a red color filter 180A, and the thirteenth to sixteenth unit pixels PX13 to PX16 of the fourth pixel group PG4 may overlap with a blue color filter 180D. The fifth to eighth unit pixels PX5 to PX8 of the second pixel group PG2 and the ninth to twelfth unit pixels PX9 to PX12 of the third pixel group PG3 may overlap with green color filters 180B and 180C, respectively.

Referring to FIG. 13, in the image sensor according to some embodiments of the present disclosure, the unit pixels included in each of the first to fourth pixel groups PG1 to PG4 may share a single micro lens 190. For example, micro lenses 190 is arranged to respectively correspond to the first to fourth pixel groups PG1 to PG4. This allows each of the first to fourth pixel groups PG1 to PG4 to provide an auto-focus (AF) function. For example, the first pixel group PG1 provides a phase detection AF (PDAF) function using divided photoelectric conversion regions 101.

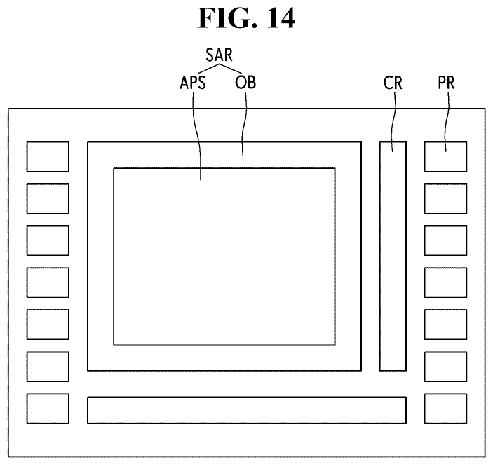

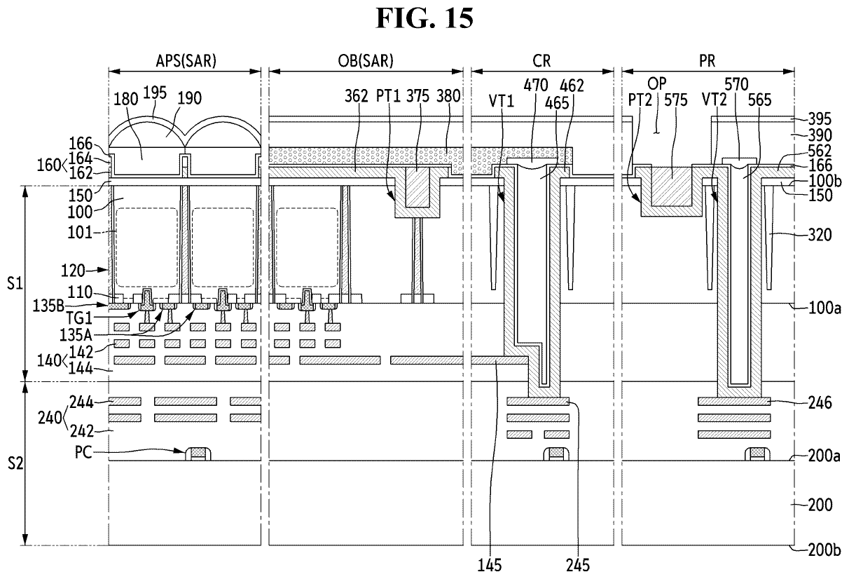

FIG. 14 is a schematic layout diagram of an image sensor according to some embodiments of the present disclosure. FIG. 15 is a schematic cross-sectional view of the image sensor of FIG. 14. For brevity, features in common with those described above with reference to FIGS. 1 to 13 may be omitted or provided a shortened description.

Referring to FIGS. 14 and 15, in some embodiments, the image sensor includes a sensor array region SAR, at least one connection region CR, and at least one pad region PR. The sensor array region SAR may include a region corresponding to the pixel array of FIG. 2. For example, a plurality of unit pixels is formed in the sensor array region SAR to be arranged two-dimensionally (e.g., in a matrix form).

The sensor array region SAR may include a light-receiving region APS and a light-shielding region OB. Active pixels that receive light and generate active signals may be arranged in the light-receiving region APS. Optical black pixels that block light and generate optical dark signals may be arranged in the light-shielding region OB. The light-shielding region OB may be formed along the periphery of the light-receiving region APS, but the present disclosure is not limited thereto.

In some embodiments, photoelectric conversion regions 101 may be formed in part of the light-shielding region OB and another part of the light-shielding region OB may be devoid of photoelectric conversion regions. For example, the photoelectric conversion regions 101 is formed in part of the light-shielding region OB adjacent to the light-receiving region APS, but may not be formed in another part of the light-shielding region OB spaced apart further away from the light-receiving region APS.

In some embodiments, dummy pixels (not illustrated) may be formed in the light-receiving region APS adjacent to the light-shielding region OB.

The connection region CR may be formed around the sensor array region SAR. The connection region CR may be formed on one side of the sensor array region SAR, but the present disclosure is not limited thereto. The connection region CR may include wirings and may be configured to transmit and receive electrical signals with the sensor array region SAR.

The pad region PR may be formed around the sensor array region SAR. The pad region PR may be formed adjacent to an edge of the image sensor, but the present disclosure is not limited thereto. The pad region PR may be connected to an external device and may be configured to transmit and receive electrical signals between the image sensor and the external device.

The connection region CR is illustrated as being interposed between the sensor array region SAR and the pad region PR, but the present disclosure is not limited thereto. Some embodiments of the present disclosure are directed to arrangements of the sensor array region SAR, the connection region CR, and the pad region PR that may be different from those shown in the drawings.

The first wiring structure 140 may include first wiring patterns 142 in the sensor array region SAR and a second wiring pattern 145 in the connection region CR. The first wiring patterns 142 may be electrically connected to the unit pixels in the sensor array region SAR. At least some of the second wiring patterns 145 may be electrically connected to at least some of the first wiring patterns 142. This allows the second wiring pattern 145 to be electrically connected to the unit pixels of the sensor array region SAR.

In some embodiments, the image sensor includes a second substrate 200 and a second wiring structure 240. The second substrate 200 may include bulk silicon or SOI. The second substrate 200 may be a silicon substrate and/or other materials, for example, SiGe, indium antimonide, a lead telluride compound, indium arsenide, indium phosphide, gallium arsenide, or gallium antimonide. The second substrate 200 may include an epitaxial layer formed on a base substrate.

The second substrate 200 may include a third surface 200a and a fourth surface 200b that are opposite each other. The third surface 200a may also be referred to as the front side of the second substrate 200, and the fourth surface 200b may also be referred to as the back side of the second substrate 200. The third surface 200a of the second substrate 200 may face the first surface 100a of the first substrate 100.

Peripheral circuit elements PC may be formed on the third surface 200a of the second substrate 200. The peripheral circuit elements PC may be electrically connected to the sensor array region SAR to transmit and receive electrical signals with the respective unit pixels of the sensor array region SAR.

The second wiring structure 240 may be integrated in the second substrate 200. In some embodiments, it may be formed on the third surface 200a of the second substrate 200. For example, the second wiring structure 240 includes a second interlayer insulating film 242 and various wiring patterns 244, 245, and 246 within the second interlayer insulating film 242. The number and arrangement of the wiring patterns 244, 245, and 246 are merely exemplary and are not particularly limited.

At least some of the wiring patterns 244, 245, and 246 of the second wiring structure 240 may be connected to the peripheral circuit elements PC. In some embodiments, the second wiring structure 240 may include third wiring patterns 244 in the sensor array region SAR, a fourth wiring pattern 245 in the connection region CR, and a fifth wiring pattern 246 in the pad region PR. The fourth wiring pattern 245 may be the uppermost wiring in the connection region CR, and the fifth wiring pattern 246 may be the uppermost wiring in the pad region PR.

The first wiring structure 140 and the second wiring structure 240 may be bonded to each other. As illustrated in FIG. 10, the upper surface of the second wiring structure 240 may be attached to the lower surface of the first wiring structure 140. The first and second wiring structures 140 and 240 may be bonded by a wafer bonding process, but the present disclosure is not limited thereto.

In some embodiments, the image sensor includes a first connection structure 362, a second connection structure 462, and a third connection structure 562. The first connection structure 362 may be formed in the light-shielding region OB. The first connection structure 362 may be formed on a surface insulating film 150 in the light-shielding region OB. The first connection structure 362 may contact part of a pixel isolation pattern 120. A first pad trench PT1 exposing the pixel isolation pattern 120 may be formed in the first substrate 100 and the surface insulating film 150 in the light-shielding region OB. The first connection structure 362 may be formed within the first pad trench PT1 to contact the pixel isolation pattern 120 in the light-shielding region OB. The first connection structure 362 may extend conformally along the profile of the side and bottom surfaces of the first pad trench PT1. The first connection structure 362 may include, for example, Ti, TiN, Ta, TaN, W, Al, Cu, or a combination thereof, but is not limited thereto.

In some embodiments, the first connection structure 362 is electrically connected to the conductive material of the pixel isolation pattern 120 (e.g., the gap-fill conductive film 123 of FIG. 3) to apply a negative bias voltage to the pixel isolation pattern 120. A first pad 375 filling the first pad trench PT1 may be formed on the first connection structure 362. The first pad 375 may include, for example, W, Cu, Al, gold (Au), silver (Ag), or an alloy thereof, but the present disclosure is not limited thereto. A first protective film 166 may cover the first connection structure 362 and the first pad 375. The first protective film 166 may extend conformally along the profiles of the first connection structure 362 and the first pad 375.

In some embodiments, the second connection structure 462 is formed in the connection region CR. The second connection structure 462 may be formed on the surface insulating film 150 in the connection region CR. The second connection structure 462 may electrically connect the first and second wiring structures 140 and 240. A first via trench VT1 exposing the second and fourth wiring patterns 145 and 245 may be formed in the connection region CR. The second connection structure 462 may be formed within the first via trench VT1 to connect the second and fourth wiring patterns 145 and 245. The second connection structure 462 may extend conformally along the profile of the bottom and side surfaces of the first via trench VT1.

The second connection structure 462 may include, Ti, TiN, Ta, TaN, W, Al, Cu, or a combination thereof, but the present disclosure is not limited thereto. In some embodiments, the second connection structure 462 is formed at the same level as the first connection structure 362.

In some embodiments, a first protective film 166 covers the second connection structure 462. The first protective film 166 may extend along the profile of the second connection structure 462. A first filling insulating film 465 filling the first via trench VT1 may be formed on the second connection structure 462. The first filling insulating film 465 may include, for example, silicon oxide, aluminum oxide, tantalum oxide, or a combination thereof, but the present disclosure is not limited thereto.

In some embodiments, a first capping pattern 470 is formed on the first filling insulating film 465. The first capping pattern 470 may cover the upper surface of the first filling insulating film 465.

In some embodiments, the third connection structure 562 is formed in the pad region PR. The third connection structure 562 may be formed on the surface insulating film 150 in the pad region PR. The third connection structure 562 may electrically connect the second wiring structure 240 to an external device, etc. A second pad trench PT2 may be formed in the first substrate 100 in the pad region PR. The third connection structure 562 may be formed within and exposed in the second pad trench PT2. Additionally, a second via trench VT2 exposing the fifth wiring pattern 246 may be formed in the pad region PR. The third connection structure 562 may be formed within the second via trench VT2 to contact the fifth wiring pattern 246. The third connection structure 562 may extend conformally along the profiles of the bottom and side surfaces of the second pad trench PT2 and the second via trench VT2. The third connection structure 562 may include, for example, Ti, TiN, Ta, TaN, W, Al, Cu, or a combination thereof, but the present disclosure is not limited thereto. In some embodiments, the third connection structure 562 may be formed at the same level as the first and second connection structures 362 and 462.

In some embodiments, a second filling insulating film 560 filling the second via trench VT2 is formed on the third connection structure 562. The second filling insulating film 560 may include silicon oxide, aluminum oxide, tantalum oxide, or a combination thereof, but the present disclosure is not limited thereto. In some embodiments, the second filling insulating film 560 is formed at the same level as the first filling insulating film 465.

In some embodiments, second pads 575 filling the second via trench VT2 is formed on the third connection structure 562. The second pads 575 may include, for example, W, Cu, Al, Au, Ag, or an alloy thereof, but the present disclosure is not limited thereto. In some embodiments, the second pads 575 is formed at the same level as the first pad 375.

In some embodiments, the first protective film 166 covers the third connection structure 562. The first protective film 166 may extend conformally along the profile of the third connection structure 562. In some embodiments, the first protective film 166 exposes the second pads 575.

In some embodiments, substrate isolation patterns 320 are formed in the first substrate 100. The substrate isolation patterns 320 are illustrated as being formed around the second and third connection structures 462 and 562, but the present disclosure is not limited thereto. The substrate isolation patterns 320 may be formed around the first connection structure 362. The substrate isolation patterns 320 may include silicon oxide, silicon nitride, silicon oxynitride, aluminum oxide, hafnium oxide, or a combination thereof, but the present disclosure is not limited thereto.

In some embodiments, the width of the substrate isolation patterns 320 may decrease from the second surface 100b of the first substrate 100 toward the first surface 100a of the first substrate 100. This may be due to the etching process for forming the substrate isolation patterns 320 being performed toward the second surface 100b of the first substrate 100. For example, each of the substrate isolation patterns 320 may be a BDTI formed by performing a DTI process on the second surface 100b of the first substrate 100. In some embodiments, the substrate isolation patterns 320 may be spaced apart from the first surface 100a of the first substrate 100.

In some embodiments, a light-shielding filter 380 is formed on the first and second connection structures 362 and 462. The light-shielding filter 380 may be formed to cover at least portions of the first protective film 166 in the light-shielding region OB and the connection region CR. The light-shielding filter 380 may block light incident on the first substrate 100.

In some embodiments, a third protective film 390 is formed on the light-shielding filter 380. The third protective film 390 may be formed to cover at least portions of the first protective film 166 in the light-shielding region OB, the connection region CR, and the pad region PR. The second protective film 195 may extend along the surface of the third protective film 390. The third protective film 390 may include a light-transmitting resin, but the present disclosure is not limited thereto. In some embodiments, the third protective film 390 is formed at the same level as micro lenses 190.

In some embodiments, the second and third protective films 195 and 390 expose the second pads 575. For example, exposure openings OP exposing the second pads 575 may be formed in the second and third protective films 195 and 390. Accordingly, the second pads 575 may be connected to an external device and may thus transmit and receive electrical signals between the image sensor and the external device. The second pads 575 may serve as input/output pads of the image sensor.

A method of fabricating an image sensor according to some embodiments of the present disclosure will hereinafter be described with reference to FIGS. 1 to 28.

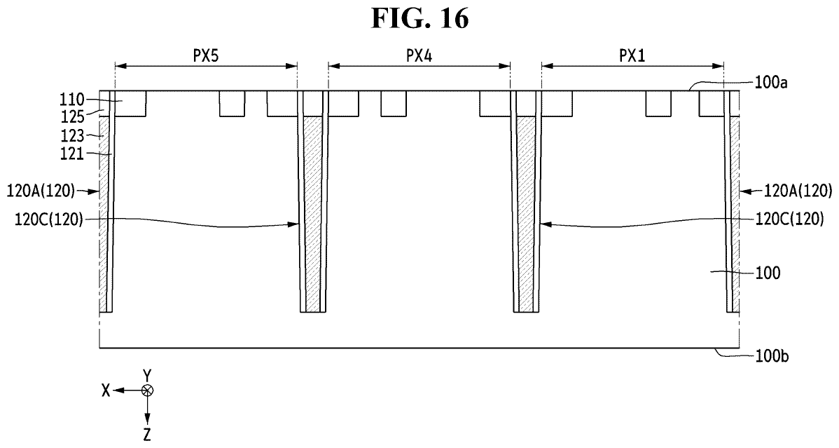

FIGS. 16 to 23 are cross-sectional views of an image sensor at various steps of its fabrication, according to some embodiments of the present disclosure. For brevity, features in common with those described above with reference to FIGS. 1 to 15 may be omitted or provided a shortened description.

Referring to FIGS. 2 and 16, in some embodiments, element isolation patterns 110 and a pixel isolation pattern 120 are formed in a first substrate 100. Shallow trenches (e.g., element isolation trenches) extending from a first surface 100a of the first substrate 100 to define active regions AR may be formed in the first substrate 100. The element isolation patterns 110 may fill at least parts of the element isolation trenches. The active regions AR may include first active patterns A1 and second active patterns A2.

Thereafter, a deep trench (e.g., a pixel isolation trench) defining a plurality of first to sixth unit pixels PX1 to PX6 may be formed in the first substrate 100. The pixel isolation pattern 120 may fill at least part of the pixel isolation trench. The pixel isolation pattern 120 may include first isolation portions 120A, second isolation portions 120B, and crossing portions 120C. The pixel isolation pattern 120 may include a liner insulating film 121, a gap-fill conductive film 123, and a buried insulating film 125.

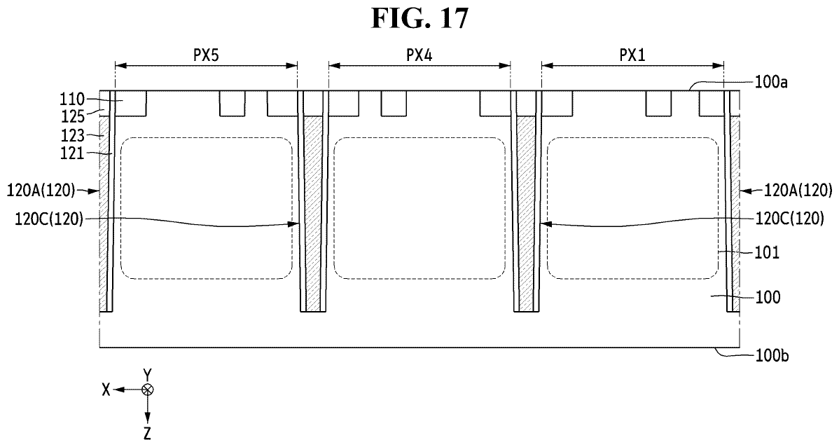

Referring to FIGS. 2 and 17, in some embodiments, photoelectric conversion regions 101 are formed in the first substrate 100. The photoelectric conversion regions 101 may be formed by ion-implanting n-type impurities into the p-type first substrate 100. The photoelectric conversion regions 101 and parts of the first substrate 100 surrounding the photoelectric conversion regions 101 may serve as photoelectric conversion elements PD of FIG. 1.

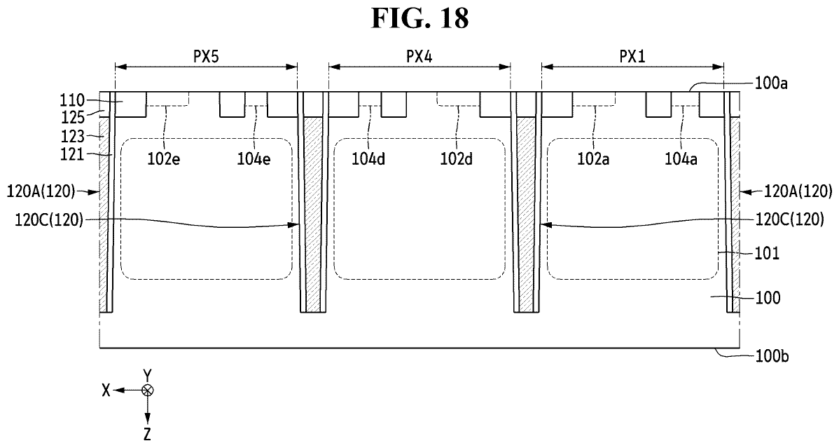

Referring to FIGS. 2 and 18, in some embodiments, first to sixth impurity regions 102a to 102f and seventh to twelfth impurity regions 104a to 104f are formed in the first substrate 100. The impurities included in the first to sixth impurity regions 102a to 102f may have a different conductivity type from the impurities included in the seventh to twelfth impurity regions 104a to 104f. For example, the first to sixth impurity regions 102a to 102f may be formed by ion-implantation of n-type impurities into the first active patterns A1. The seventh to twelfth impurity regions 104a to 104f may be formed by ion-implanting p-type impurities into the second active patterns A2.

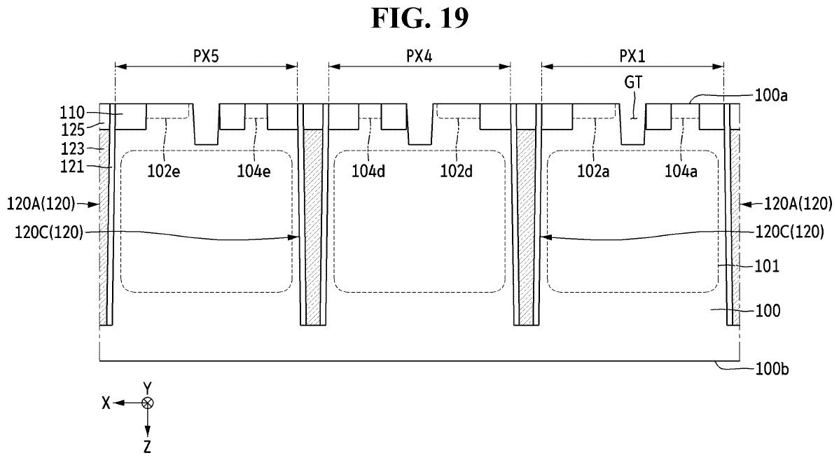

Referring to FIGS. 2 and 19, in some embodiments, gate trenches GT are formed in the first substrate 100. The gate trenches GT may extend from the first surface 100a. The gate trenches GT may be respectively formed in the first to sixth unit pixels PX1 to PX6. The gate trenches GT may be adjacent to the first to sixth impurity regions 102a to 102f.

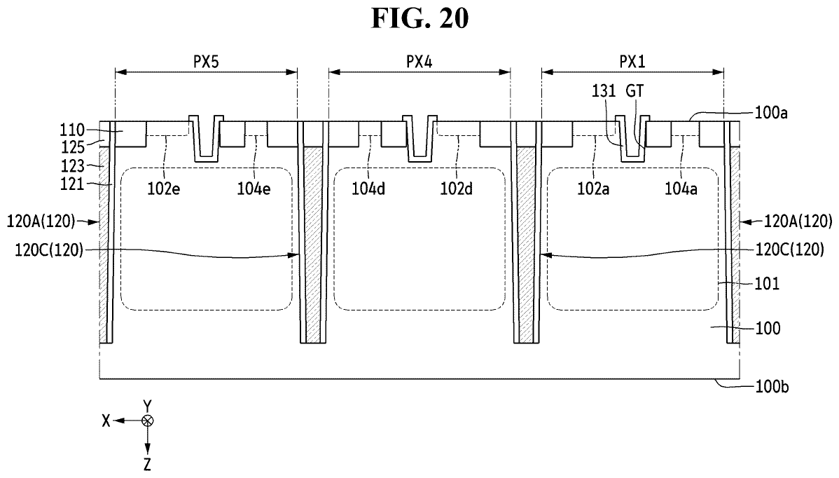

Referring to FIGS. 2 and 20, in some embodiments, a gate dielectric film 131 is formed. A dielectric film conformally extending on the structure resulting from FIG. 19 may be formed. Thereafter, the dielectric film may be patterned to form the gate dielectric film 131.

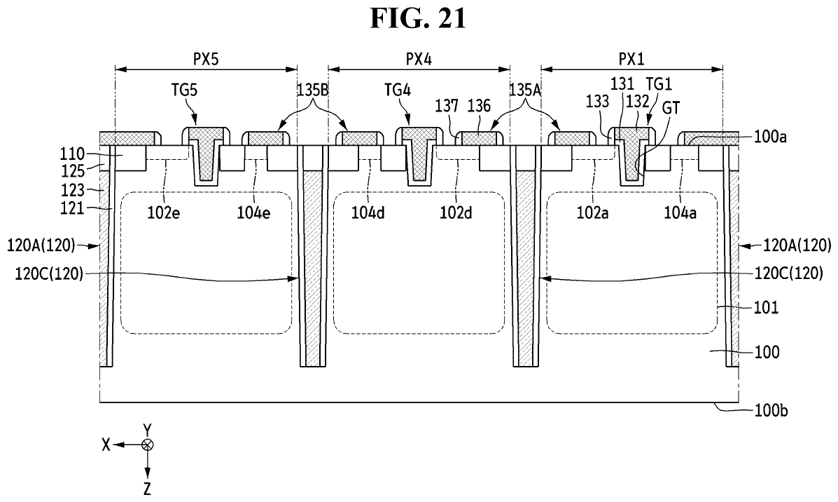

Referring to FIGS. 2 and 21, in some embodiments, first to sixth gate structures GS1 to GS6, first to sixth transfer gate structures TG1 to TG6, a first pad structure 135A, and a second pad structure 135B are formed on the first surface 100a of the first substrate 100. A conductive film conformally extending on the structure resulting from FIG. 20 may be formed. Thereafter, the conductive film may be patterned to form a gate electrode film 132 and a pad conductive film 136. A spacer film may be formed on the gate electrode film 132 and the pad conductive film 136. Thereafter, the spacer film may be patterned to form gate spacers 133 and pad spacers 137.

The gate dielectric film 131, the gate electrode film 132, and the gate spacers 133 may form the first to sixth gate structures GS1 to GS6 and the first to sixth transfer gate structures TG1 to TG6. The pad conductive film 136 and the pad spacers 137 may form the first and second pad structures 135A and 135B.

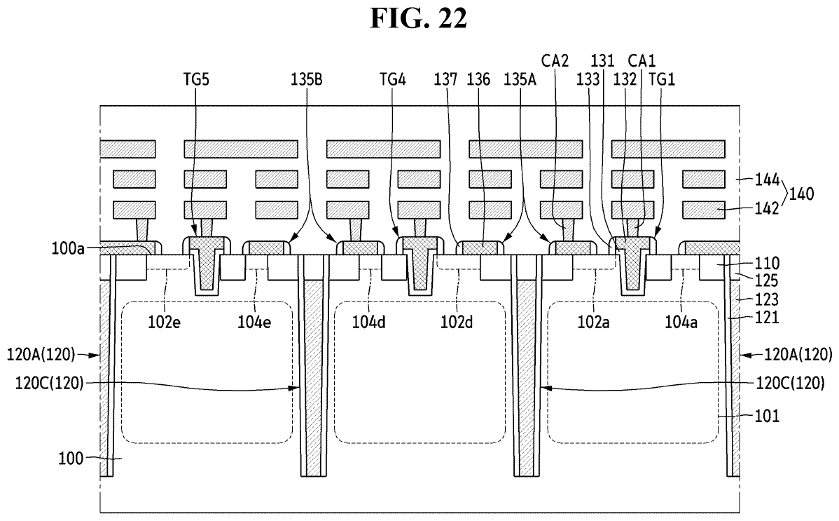

Referring to FIGS. 2 and 22, in some embodiments, a first wiring structure 140 is formed on the first surface 100a of the first substrate 100. The first wiring structure 140 may be electrically connected to the first to sixth gate structures GS1 to GS6, the first to sixth transfer gate structures TG1 to TG6, the first pad structure 135A, and/or the second pad structure 135B. The first contacts CA1 connected to at least one of the first to sixth transfer gate structures TG1 to TG6 may be formed. The second contacts CA2 connected to one of the first and second pad structures 135A and 135B may be formed. In some embodiments, the first contacts CA1 and the second contacts CA2 are formed at the same level. Thereafter, first wiring patterns 142 electrically connected to the first contacts CA1 and/or the second contacts CA2 may be formed.

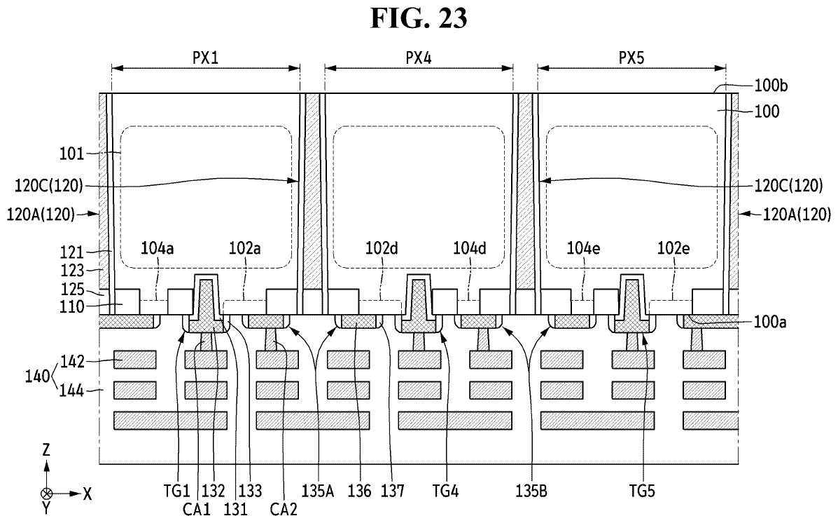

Referring to FIGS. 2 and 23, in some embodiments, a back grinding process is performed on a second surface 100b of the first substrate 100. As the back grinding process is performed, the pixel isolation pattern 120 may be exposed from the second surface 100b of the first substrate 100. A pixel isolation pattern 120 penetrating the first substrate 100 may be provided. Thereafter, referring to FIGS. 2 and 3, a surface insulating film 150, a grid pattern 160, a first protective film 166, color filters 180, and micro lenses 190 are formed on the second surface 100b of the first substrate 100. In this manner, the image sensor described above with reference to FIGS. 1 to 3 can be provided.

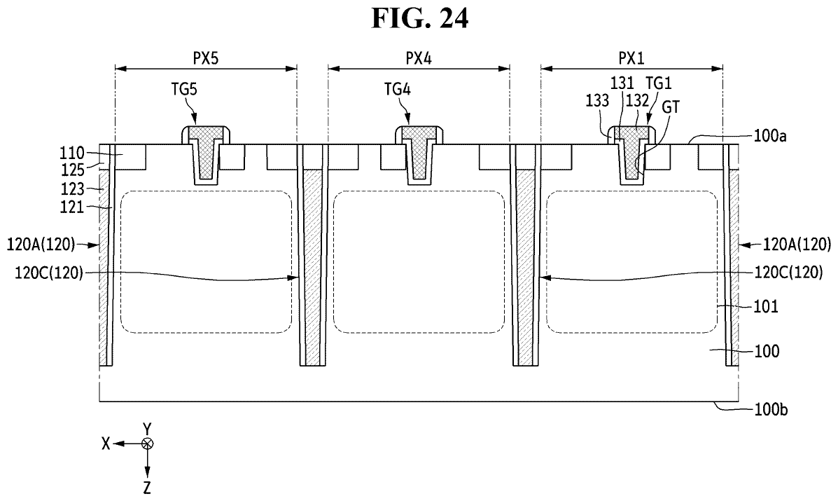

FIGS. 24 to 26 are cross-sectional views of an image sensor at various steps of its fabrication, according to some embodiments of the present disclosure. For brevity, features in common with those described above with reference to FIGS. 1 to 23 may be omitted or provided a shortened description. FIG. 24 illustrates a step that follows the step illustrated in FIG. 17.

Referring to FIGS. 2 and 24, in some embodiments, first to sixth gate structures GS1 to GS6 and first to sixth transfer gate structures TG1 to TG6 are formed on a first surface 100a of a first substrate 100. The formation of the first to sixth gate structures GS1 to GS6 and the first to sixth transfer gate structures TG1 to TG6 may be performed as described above with reference to FIGS. 19 to 21.

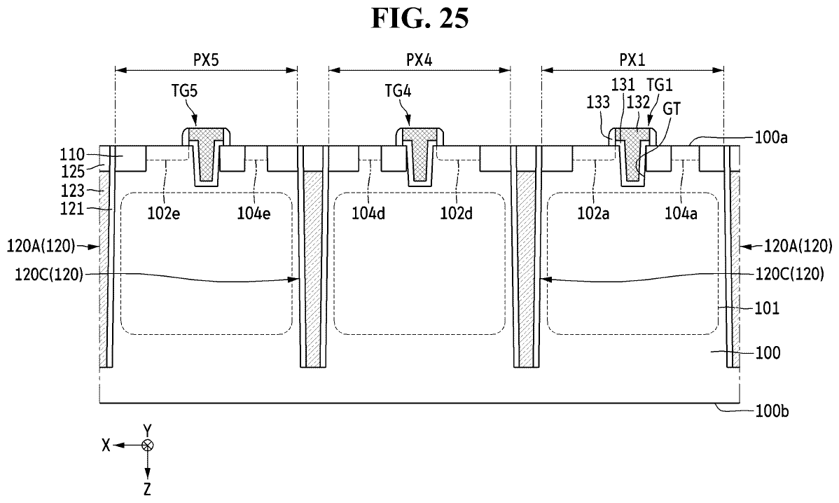

Referring to FIGS. 2 and 25, in some embodiments, first to sixth impurity regions 102a to 102f and seventh to twelfth impurity regions 104a to 104f are formed in the first substrate 100. The formation of the first to sixth impurity regions 102a to 102f and the seventh to twelfth impurity regions 104a to 104f may be performed as described above with reference to FIG. 18.

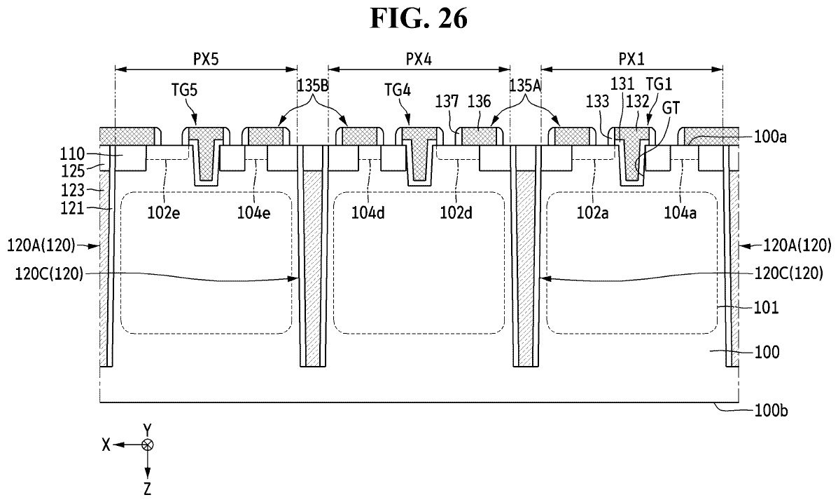

Referring to FIGS. 2 and 26, in some embodiments, a first pad structure 135A and a second pad structure 135B are formed on the first surface 100a of the first substrate 100. The formation of the first and second pad structures 135A and 135B may be performed as described above with reference to FIG. 21.

Thereafter, the steps described above with reference to FIGS. 22, 23, and 3 may be performed. In this manner, the image sensor described above with reference to FIGS. 2 and 4 can be provided.

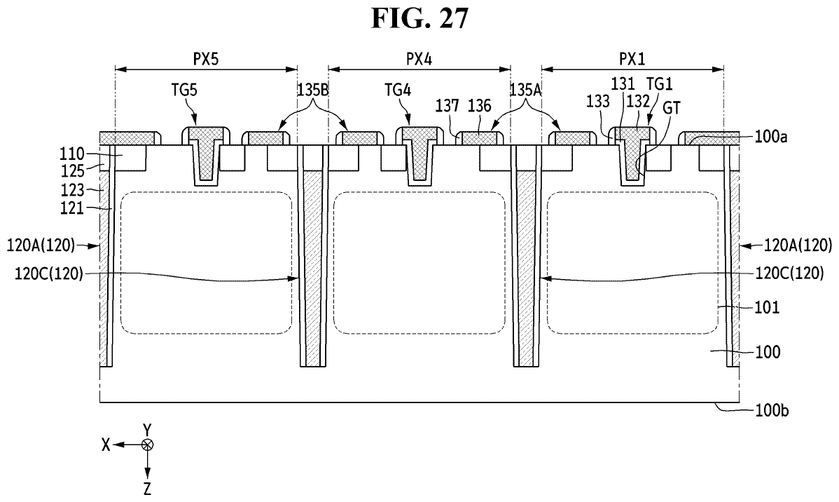

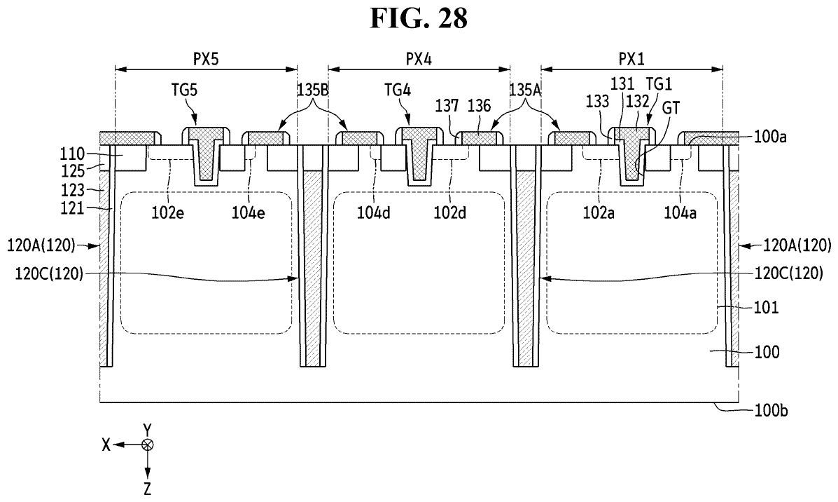

FIGS. 27 and 28 are cross-sectional views of an image sensor at various steps of its fabrication, according to some embodiments of the present disclosure. For brevity, features in common with those described above with reference to FIGS. 1 to 23 may be omitted or provided a shortened description. FIG. 27 illustrates a step that follows the step illustrated in FIG. 17.

Referring to FIGS. 2 and 27, in some embodiments, first to sixth gate structures GS1 to GS6, first to sixth transfer gate structures TG1 to TG6, a first pad structure 135A, and a second pad structure 135B are formed on a first surface 100a of a first substrate 100. The formation of the first to sixth gate structures GS1 to GS6, the first to sixth transfer gate structures TG1 to TG6, the first pad structure 135A, and the second pad structure 135B may be performed as described above with reference to FIGS. 19 to 21.

Referring to FIGS. 2 and 28, in some embodiments, first to sixth impurity regions 102a to 102f and seventh to twelfth impurity regions 104a to 104f are formed in the first substrate 100. The formation of the first to sixth impurity regions 102a to 102f and the seventh to twelfth impurity regions 104a to 104f may be performed as described above with reference to FIG. 18.

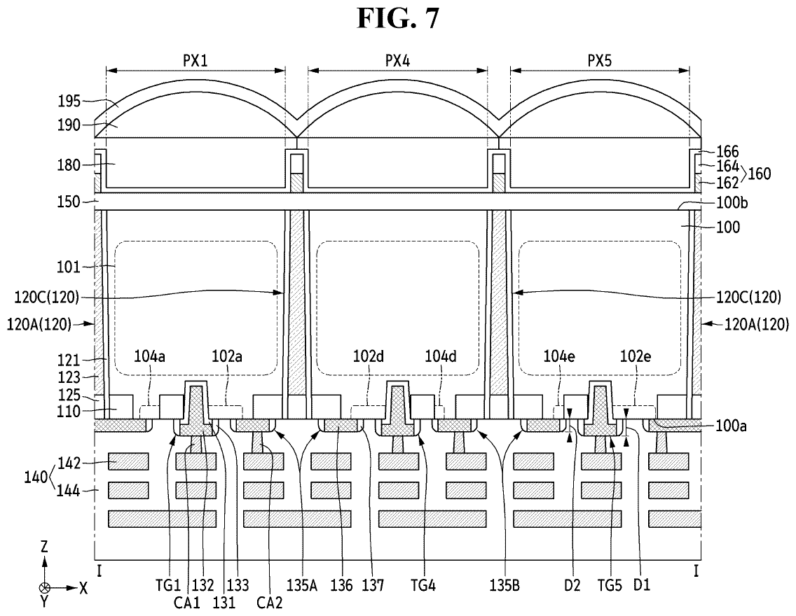

Thereafter, the steps described above with reference to FIGS. 22, 23, and 3 may be performed. In this manner, the image sensor described above with reference to FIGS. 2 and 7 can be provided.

It will be appreciated that the embodiments of the present disclosure are not limited to the exact construction that has been described above and illustrated in the accompanying drawings and that various modifications and changes may be made without departing from the scope thereof.

What is claimed is:

1. An image sensor comprising:
a substrate comprising a first surface and a second surface opposite to the first surface;
a pixel isolation pattern in the substrate, the pixel isolation pattern defining a first unit pixel, a second unit pixel adjacent to the first unit pixel in a first direction, a third unit pixel adjacent to the first unit pixel in a second direction that intersects the first direction, and a fourth unit pixel adjacent to the second unit pixel in the second direction and adjacent to the third unit pixel in the first direction;
photoelectric conversion regions within the first to fourth unit pixels, respectively;
first to fourth impurity regions within the first to fourth unit pixels, respectively, and adjacent to the first surface; and
a first pad structure on the first surface, the first pad structure contacting the first to fourth impurity regions,
wherein the first pad structure comprises a first hole exposing the pixel isolation pattern disposed between the first unit pixel and the fourth unit pixel.

2. The image sensor of claim 1, wherein the second surface is a light-receiving surface configured to receive incident light.

3. The image sensor of claim 1, wherein each of the first to fourth impurity regions comprises impurities of the same conductivity type as the photoelectric conversion regions.

4. The image sensor of claim 1, wherein each of the first to fourth impurity regions comprises impurities of a different conductivity type from the photoelectric conversion regions.

5. The image sensor of claim 1, wherein
the pixel isolation pattern further defines a fifth unit pixel adjacent to the second unit pixel in the first direction and a sixth unit pixel adjacent to the fourth unit pixel in the first direction and adjacent to the fifth unit pixel in the second direction,
the image sensor further comprises:
fifth to eighth impurity regions within the second, fourth to sixth unit pixels, respectively, and adjacent to the first surface; and
a second pad structure on the first surface, the second pad structure spaced apart from the first pad structure and contacting the fifth to eighth impurity regions,
each of the fifth to eighth impurity regions comprises impurities of a different conductivity type from the first to fourth impurity regions, and
the second pad structure comprises a second hole exposing the pixel isolation pattern disposed between the second unit pixel and the sixth unit pixel.

6. The image sensor of claim 1, wherein the pixel isolation pattern contacts both the first surface and the second surface.

7. The image sensor of claim 1, wherein a width of the pixel isolation pattern decreases from the first surface toward the second surface.

8. The image sensor of claim 1, wherein the pixel isolation pattern comprises a liner insulating film and a gap-fill conductive film sequentially stacked on an inner wall of the substrate.

9. The image sensor of claim 1, further comprising:
first to fourth gate structures disposed on the first surface of each of the first to fourth unit pixels, respectively,
wherein
each of the first to fourth gate structures includes a gate dielectric film and a gate electrode film that are sequentially stacked, and
the first pad structure includes a pad conductive film of the same conductive material as the gate electrode film.

10. The image sensor of claim 1, wherein the first pad structure comprises a polysilicon film.

11. An image sensor comprising:
a substrate having a first surface and a second surface opposite to the first surface;
a pixel isolation pattern in the substrate, the pixel isolation pattern defining a plurality of unit pixels arranged two-dimensionally along a first direction and a second direction that intersects the first direction;
photoelectric conversion regions within the respective unit pixels;
element isolation patterns defining active regions within the respective unit pixels adjacent to the first surface; and
a pad structure on the first surface,
wherein
the pixel isolation pattern comprises a first isolation portion extending in the second direction, a second isolation portion extending in the first direction, and a crossing portion where the first isolation portion and the second isolation portion intersect,
the unit pixels comprise a first unit pixel, a second unit pixel separated from the first unit pixel by the first isolation portion, a third unit pixel separated from the first unit pixel by the second isolation portion, and a fourth unit pixel separated from the first unit pixel by the crossing portion, and
the pad structure connects the active regions of the first to fourth unit pixels and does not overlap with the crossing portion.

12. The image sensor of claim 11, wherein the pad structure overlaps with a part of the first isolation portion and a part of the second isolation portion.

13. The image sensor of claim 11, wherein the pad structure forms a closed loop extending across the first to fourth unit pixels.

14. The image sensor of claim 11, wherein the pixel isolation pattern comprises a liner insulating film and a gap-fill conductive film that are sequentially stacked on an inner wall of the substrate.

15. The image sensor of claim 14, wherein the gap-fill conductive film is configured to receive a bias signal to adjust electrical characteristics in the image sensor.

16. An image sensor comprising:
a substrate having a first surface and a second surface opposite the first surface;
a pixel isolation pattern in the substrate, the pixel isolation pattern defining a first unit pixel, a second unit pixel adjacent to the first unit pixel in a first direction, a third unit pixel adjacent to the first unit pixel in a second direction intersecting the first direction, and a fourth unit pixel adjacent to the second unit pixel in the second direction and adjacent to the third unit pixel in the first direction;
photoelectric conversion regions within the first to fourth unit pixels, respectively;
element isolation patterns defining active regions within the first to fourth unit pixels adjacent to the first surface, respectively;
first to fourth transfer gate structures disposed on the active regions of the first to fourth unit pixels, respectively;
first to fourth floating diffusion regions within the active regions adjacent to the first to fourth transfer gate structures, respectively; and
a first pad structure on the first surface, the first pad structure spaced apart from the first to fourth transfer gate structures and connecting the first to fourth floating diffusion regions,
wherein the first pad structure comprises a first hole exposing the pixel isolation pattern disposed between the first unit pixel and the fourth unit pixel.

17. The image sensor of claim 16, wherein
each of the first to fourth transfer gate structures comprises a gate dielectric film and a gate electrode film that are sequentially stacked on the active regions, and
the first pad structure comprises a pad conductive film of the same conductive material as the gate electrode film.

18. The image sensor of claim 17, wherein a height of the gate electrode film is greater than a height of the pad conductive film with respect to the first surface.

19. The image sensor of claim 17, wherein
each of the first to fourth transfer gate structures further comprises a gate spacer extending along a side surface of the gate electrode film, and
the first pad structure further comprises a pad spacer extending along a side surface of the pad conductive film and including the same insulating material as the gate spacer.

20. The image sensor of claim 16, wherein
the pixel isolation pattern further defines a fifth unit pixel adjacent to the second unit pixel in the first direction, and a sixth unit pixel adjacent to the fourth unit pixel in the first direction and adjacent to the fifth unit pixel in the second direction,
the image sensor further comprises:
first to fourth ground regions within the active regions of the second, fourth to sixth unit pixels, respectively; and
a second pad structure on the first surface, the second pad structure spaced apart from the first pad structure and connecting the first to fourth ground regions, and
the second pad structure comprises a second hole exposing the pixel isolation pattern disposed between the second unit pixel and the sixth unit pixel.
